(19) United States
(12) Patent Application Publication
(10) Pub. No.: US 2025/0293049 A1
(43) Pub. Date: Sep. 18, 2025

(54) FAN-OUT CHIP PACKAGING METHOD

(71) Applicant: TONGFU MICROELECTRONICS CO., LTD., Nantong (CN)

(72) Inventors: Lei SHI, Nantong (CN); Xin XIA, Nantong (CN); Yujuan TAO, Nantong (CN)

(21) Appl. No.: 19/223,692

(22) Filed: May 30, 2025

Related U.S. Application Data
(63) Continuation of application No. PCT/CN2023/136622, filed on Dec. 6, 2023.

(30) Foreign Application Priority Data
Dec. 6, 2022 (CN) 202211553696.1
Dec. 6, 2022 (CN) 202211553758.9
Dec. 6, 2022 (CN) 202211554549.6
Dec. 6, 2022 (CN) 202211555058.3
Dec. 6, 2022 (CN) 202211555419.4
Dec. 6, 2022 (CN) 202211555903.7
Dec. 6, 2022 (CN) 202211556459.0
Dec. 6, 2022 (CN) 202211556609.8
Dec. 6, 2022 (CN) 202211557780.0
Dec. 6, 2022 (CN) 202211557781.5
Dec. 6, 2022 (CN) 202211557789.1
Dec. 6, 2022 (CN) 202211557809.5
Dec. 6, 2022 (CN) 202211558289.X
Dec. 6, 2022 (CN) 202211558474.9
Dec. 6, 2022 (CN) 202211558476.8
Dec. 6, 2022 (CN) 202211578865.7

(51) Int. Cl. H01L 21/48; H01L 21/56; H01L 21/683; H01L 23/00; H01L 23/29; H01L 23/31; H01L 23/538; H01L 25/065

(52) U.S. Cl. CPC H01L 21/4846; H01L 21/56; H01L 21/6835; H01L 23/293; H01L 23/5385; H01L 23/5386; H01L 24/08; H01L 24/80; H01L 25/0655; H01L 23/3128; H01L 2221/68372; H01L 2224/08225; H01L 2224/80895; H01L 2224/80896; H01L 2924/1815

(57) ABSTRACT

A fan-out chip packaging method and a fan-out chip packaging structure are provided. The method includes: providing a carrier, silicon wafers, and chips; forming conductive connection structures on the silicon wafers respectively to form silicon interposer plates; cutting each silicon interposer plate respectively to obtain silicon interposer sub-plates; selecting target silicon interposer sub-plates from the silicon interposer sub-plates according to preset packaging requirements, and fixing the target silicon interposer sub-plates on the carrier; forming a first plastic encapsulation layer on a side of the target silicon interposer sub-plates away from the carrier; and interconnecting the chips to the target silicon interposer sub-plates. The conductive connection structures on at least one silicon interposer plate are different from the conductive connection structures on other silicon interposer plates.

### CROSS-REFERENCE TO RELATED APPLICATION

This application is a continuation application of PCT Patent Application No. PCT/CN2023/136622, filed on Dec. 6, 2023, which claims the priority of Chinese Patent Application Nos.: CN202211555058.3, CN202211555419.4, CN202211553696.1, CN202211558289.X, CN202211557781.5, CN202211556609.8, CN202211557809.5, CN202211558476.8, CN202211578865.7, CN202211555903.7, CN202211556459.0, CN202211557789.1, CN202211557780.0, CN202211558474.9, CN202211553758.9, and CN202211554549.6, all filed on Dec. 6, 2022, the contents of all of which are incorporated herein by reference in their entirety.

### TECHNICAL FIELD

The present disclosure generally relates to the field of semiconductor packaging technology and, more particularly, relates to a fan-out chip packaging method and a fan-out chip packaging structure.

### BACKGROUND

In fan-out 2.5D packaging technology, a silicon interposer is mainly connected between chips and a substrate to amplify and transmit signals from the chip to the substrate. The integration level of the existing silicon interposer and the chips still needs to be further improved. The chip package becomes thinner and thinner, and a plurality of chips may be connected to the silicon interposer. Therefore, when chips are installed on a silicon interposer and the silicon interposer is thinned, the silicon interposer is prone to warp or even rupture.

Therefore, there is a need to provide a fan-out chip packaging method that is reasonably designed and could alleviate above problems.

### SUMMARY

One aspect of the present disclosure provides a fan-out chip packaging method. The method includes: providing a carrier, a plurality of silicon wafers, and a plurality of chips; forming conductive connection structures on the plurality of silicon wafers respectively to form a plurality of silicon interposer plates; cutting each of the plurality of silicon interposer plates respectively to obtain a plurality of silicon interposer sub-plates; selecting a plurality of target silicon interposer sub-plates from the plurality of silicon interposer sub-plates according to preset packaging requirements, and fixing the plurality of target silicon interposer sub-plates on the carrier; forming a first plastic encapsulation layer on a side of the plurality of target silicon interposer sub-plates away from the carrier; and interconnecting the plurality of chips to the plurality of target silicon interposer sub-plates. The conductive connection structures on at least one of the plurality of silicon interposer plates are different from the conductive connection structures on others of the plurality of silicon interposer plates.

Another aspect of the present disclosure provides a fan-out chip packaging structure. The structure includes: a plurality of silicon interposers; a first plastic encapsulation layer wrapping the plurality of silicon interposers; and a plurality of chips. Each of the plurality of silicon interposers is provided with conductive connection structures and conductive connection structures of at least one of the plurality of silicon interposers are different from conductive connection structures of others of the plurality of silicon interposers. The plurality of chips is interconnected to the plurality of silicon interposers through a bonding structure

### BRIEF DESCRIPTION OF THE DRAWINGS

The following drawings are merely examples for illustrative purposes according to various disclosed embodiments and are not intended to limit the scope of the present disclosure.

FIG. 1 illustrates an exemplary fan-out chip packaging method according to various disclosed embodiments of the present disclosure.

FIG. 2 illustrates an exemplary method for forming blind holes on a silicon wafer according to various disclosed embodiments of the present disclosure.

FIG. 3 illustrates an exemplary structure of a first silicon interposer plate and a first conductive structure according to various disclosed embodiments of the present disclosure.

FIG. 4 and FIG. 5 illustrate an exemplary packaging process of a second silicon interposer plate and a second conductive structure according to various disclosed embodiments of the present disclosure.

FIG. 6 to FIG. 8 illustrate an exemplary packaging process of a third silicon interposer plate and a third conductive structure according to various disclosed embodiments of the present disclosure.

FIG. 9 to FIG. 11 illustrate an exemplary packaging process of a fourth silicon interposer plate and a fourth conductive structure according to various disclosed embodiments of the present disclosure.

FIG. 12 illustrates an exemplary structure of a first silicon interposer sub-plate according to various disclosed embodiments of the present disclosure.

FIG. 13 illustrates an exemplary structure of a second silicon interposer sub-plate according to various disclosed embodiments of the present disclosure.

FIG. 14 illustrates an exemplary structure of a third silicon interposer sub-plate according to various disclosed embodiments of the present disclosure.

FIG. 15 illustrates an exemplary structure of a fourth silicon interposer sub-plate according to various disclosed embodiments of the present disclosure.

FIG. 16 to FIG. 20 illustrate structures corresponding to different stages of an exemplary fan-out chip packaging method according to various disclosed embodiments of the present disclosure.

FIG. 21 to FIG. 25 illustrate structures corresponding to different stages of another exemplary fan-out chip packaging method according to various disclosed embodiments of the present disclosure.

FIG. 26 to FIG. 31 illustrate structures corresponding to different stages of another exemplary fan-out chip packaging method according to various disclosed embodiments of the present disclosure.

FIG. 32 to FIG. 36 illustrate structures corresponding to different stages of another exemplary fan-out chip packaging method according to various disclosed embodiments of the present disclosure.

FIG. 37 to FIG. 41 illustrate structures corresponding to different stages of another exemplary fan-out chip packaging method according to various disclosed embodiments of the present disclosure.

FIG. 42 to FIG. 57 illustrate structures corresponding to different stages of another exemplary fan-out chip packaging method according to various disclosed embodiments of the present disclosure.

FIG. 58 to FIG. 63 illustrate structures corresponding to different stages of another exemplary fan-out chip packaging method according to various disclosed embodiments of the present disclosure.

FIG. 64 to FIG. 69 illustrate structures corresponding to different stages of another exemplary fan-out chip packaging method according to various disclosed embodiments of the present disclosure.

FIG. 70 to FIG. 72 illustrate structures corresponding to different stages of another exemplary fan-out chip packaging method according to various disclosed embodiments of the present disclosure.

FIG. 73 to FIG. 76 illustrate structures corresponding to different stages of another exemplary fan-out chip packaging method according to various disclosed embodiments of the present disclosure.

### DETAILED DESCRIPTION

Reference will now be made in detail to exemplary embodiments of the disclosure, which are illustrated in the accompanying drawings. Wherever possible, the same reference numbers will be used throughout the drawings to refer to the same or like parts.

It should be noted that “surface” or “upper” in this specification are used to describe the relative positional relationship in space, and are not limited to whether components are in direct contact.

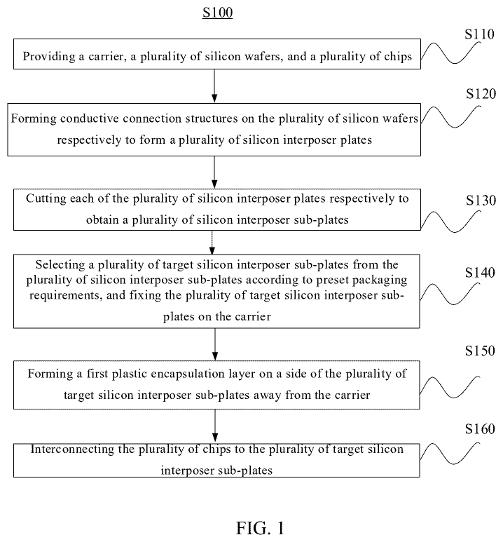

One embodiment of the present disclosure provides a fan-out chip packaging method S100. As shown in FIG. 1, the method S100 may include S110 to S160.

In S110, a carrier, a plurality of silicon wafers, and a plurality of chips may be provided.

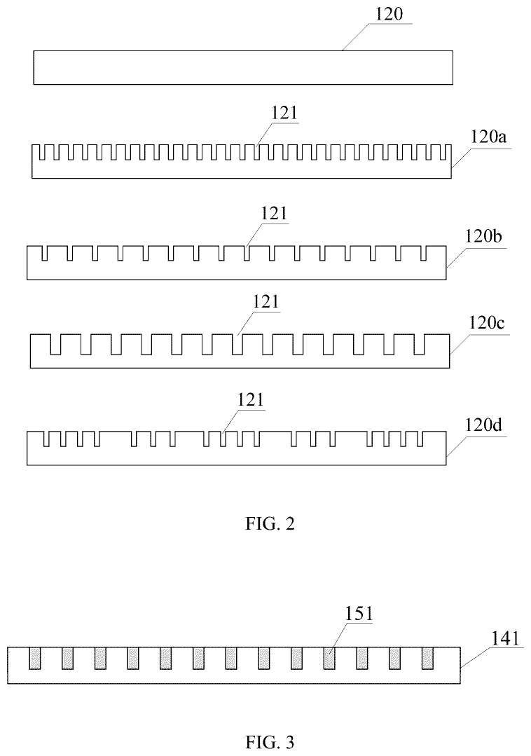

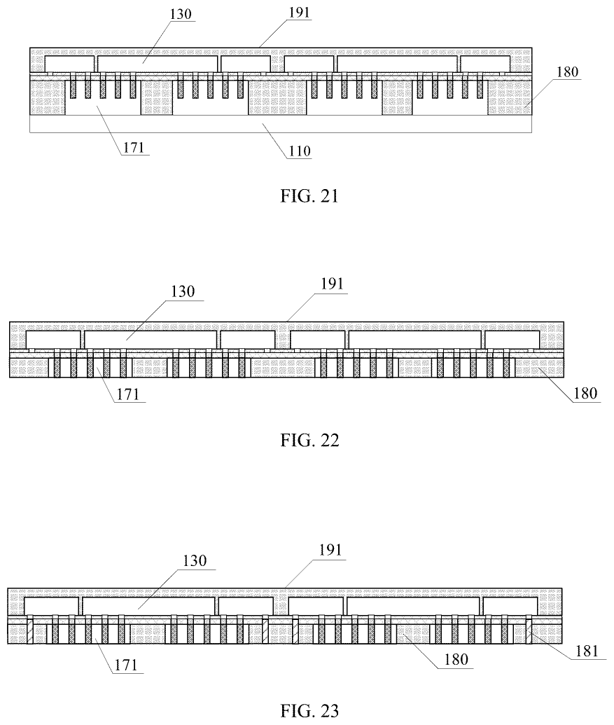

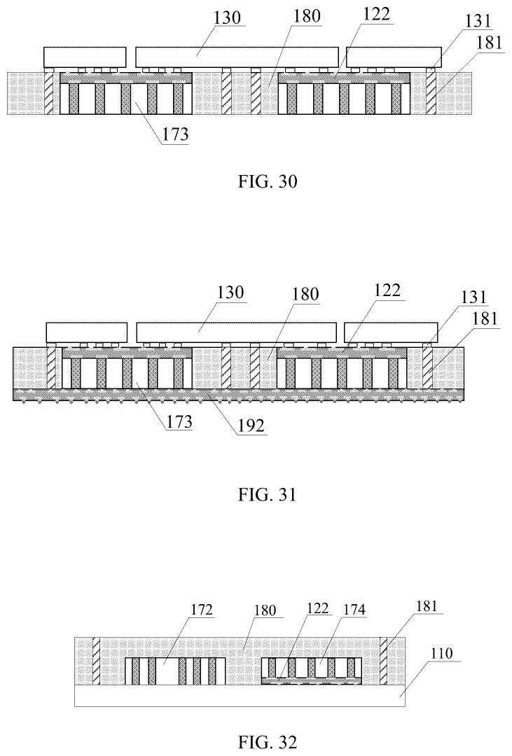

As shown in FIG. 2 to FIG. 40, the carrier 110, the plurality of silicon wafers 120 and the plurality of chips 130 may be provided. The carrier 110 may be made of a material including glass, a silicon wafer or a metal, which is not limited in the present disclosure. The present disclosure also has no limit on the number of the plurality of silicon wafers 120 and the number of the plurality of chips 130, which may be configured according to actual needs.

In one embodiment, the plurality of chips 130 may be chips of a same type. In some other embodiments, the plurality of chips 130 may include a plurality of heterogeneous chips. That is, the plurality of heterogeneous chips may be packaged into a same package.

In S120, conductive connection structures may be formed on the plurality of silicon wafers respectively, to form a plurality of silicon interposer plates. The conductive connection structures on at least one of the plurality of silicon interposer plates may be different from the conductive connection structures on others of the plurality of silicon interposer plates.

As shown in FIG. 2 to FIG. 11, in one embodiment, the conductive connection structures (not shown in the figures) may be formed on the plurality of silicon wafers 120 respectively, to form the plurality of silicon interposer plates. The conductive connection structures on at least one of the plurality of silicon interposer plates may be different from the conductive connection structures on others of the plurality of silicon interposer plates. That is, different conductive connection structures may be formed on different silicon interposer plates.

In the present disclosure, the conductive connection structures may be formed on the plurality of silicon wafers respectively, to form the plurality of silicon interposer plates. The fabrication process may be simple and the difficulty of the process may be low. The conductive connection structures on at least one of the plurality of silicon interposer plates may be different from the conductive connection structures on others of the plurality of silicon interposer plates. Packaging with a high integration level may be achieved, while packaging requirements of packaging the plurality of silicon interposer plates and the plurality of chips may be satisfied.

In one embodiment, as shown in FIG. 2 and FIG. 3, S120 may include S101 to S102.

In S101: forming a plurality of blind holes may be formed on a front surface of at least one silicon wafer of the plurality of silicon wafers. The plurality of blind holes on at least one of the plurality of silicon wafers may be different from the plurality of blind holes on others of the plurality of silicon wafers

In one embodiment, as shown in FIG. 2, through photolithography and etching processes, the plurality of blind holes 121 may be formed on the front surface of the at least one silicon wafer 120. Then, an insulating layer, a diffusion barrier layer, and a seed layer (not shown in the figure) may be deposited on sidewalls of each blind hole 121. The plurality of blind holes 121 formed on the front surface of at least one silicon wafer 120 may be different from the plurality of blind holes 121 formed on the front surfaces of the remaining silicon wafers 120.

That is, the plurality of blind holes 121 with different heights, depths, widths, or space may be formed on different silicon wafers. For example, in one embodiment, the plurality of blind holes 121 on each silicon wafer 120 may have a different ratio between height, depth and width, or the distance between the plurality of blind holes 121 may be different. For example, in one embodiment shown in FIG. 1, the plurality of blind holes 121 equally spaced with relatively small space may be formed on a first silicon wafer 120a, the plurality of blind holes 121 equally spaced with a relatively large space may be formed on a second silicon wafer 120b, the plurality of blind holes 121 equally spaced with a relatively large space, depth, height, and width, may be formed on a third silicon wafer 120c, and the plurality of blind holes 121 with different and large space, and small depth, height and width may be formed on a fourth silicon wafer 120d. The specifications of the plurality of blind holes 121 on each silicon wafer 120 may also have other configurations, which are not limited in the present disclosure.

In the present disclosure, the plurality of blind holes formed on the front surface of at least one silicon wafer may be different from the plurality of blind holes formed on the front surfaces of the remaining silicon wafers. Therefore, the conductive connection structures with different integration levels may be formed, improving the overall integration level of the packaging.

In S102, the plurality of blind holes may be filled with conductive materials to form the conductive connection structures.

As shown in FIG. 3, in one embodiment, the conductive materials may be filled into the plurality of blind holes 121 through processes including electroplating, and then the surfaces of the plurality of blind holes 121 may be planarized through a chemical mechanical polishing process to form the conductive connection structures, that is, first conductive connection structures 151.

As shown in FIG. 3, in the present embodiment, the first conductive connection structures 151 may be formed on the plurality of silicon wafers 120 to form the first silicon interposer plates 141. That is, the first silicon interposer plate 141 may be provided with the plurality of blind holes 121 filled with conductive materials.

In another embodiment shown in FIG. 2 to FIG. 5, S120 may include:

S201: forming a plurality of blind holes 121 on the front surface of at least one silicon wafer 120, where the plurality of blind holes 121 formed on the front surface of at least one silicon wafer 120 may be different from the plurality of blind holes 121 formed on the front surfaces of the remaining silicon wafers 120, as shown in FIG. 2;

S202: filling the plurality of blind holes 121 with conductive materials, as shown in FIG. 3; and

S203: thinning back surfaces of the plurality of silicon wafers until exposing the plurality of blind holes, to form the conductive connection structures.

For S201 and S202, references may be made to the previous description about S101 and S102.

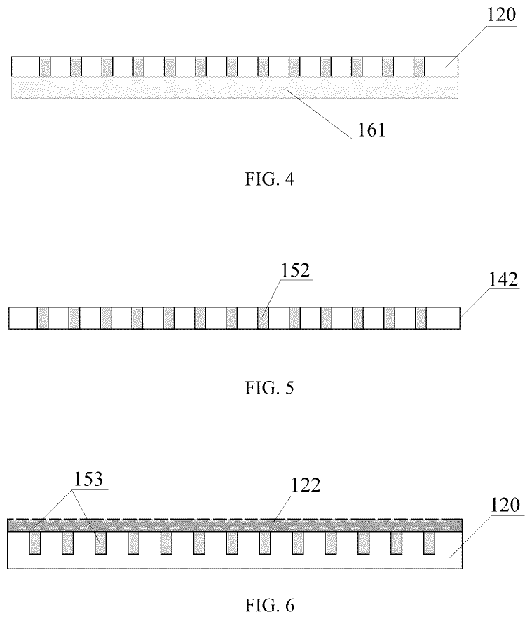

In one embodiment, after the plurality of blind holes 121 is filled with conductive materials through a process including electroplating, as shown in FIG. 4, the front surfaces of the plurality of silicon wafers 120 may be fixed on a temporary carrier 160, and then the back surfaces of the plurality of silicon wafers 120 may be ground and thinned until the plurality of blind holes 121 is exposed. As shown in FIG. 5, the temporary carrier 160 may be removed to form the conductive connection structures. That is, in this embodiment, after the plurality of blind holes 121 is filled with conductive material, the front surfaces of the plurality of silicon wafers 120 may be fixed on the temporary carrier 160, and a grinding process may be used to grind the back surfaces of the plurality of silicon wafers 120 to remove excess silicon material, and then the temporary carrier 160 may be removed to form the second conductive connection structures 152. The second conductive connection structures 152 may be silicon through holes filled with conductive materials.

As shown in FIG. 5, in the present embodiment, the second conductive connection structures 152 may be formed on the plurality of silicon wafers 120 to form the second silicon interposer plates 142. That is, the second silicon interposer plate 142 may be provided with silicon through holes for leading out the functions of the second silicon interposer plates 142.

In another embodiment shown in FIG. 2 to FIG. 8, S120 may include:

S301: forming a plurality of blind holes 121 on the front surface of at least one silicon wafer 120, where the plurality of blind holes 121 formed on the front surface of at least one silicon wafer 120 may be different from the plurality of blind holes 121 formed on the front surfaces of the remaining silicon wafers 120, as shown in FIG. 2;

S302: filling the plurality of blind holes 121 with conductive materials, as shown in FIG. 3;

S303: forming a redistribution layer on the plurality of blind holes 121; and

S304: thinning back surfaces of the plurality of silicon wafers until exposing the plurality of blind holes, to form the conductive connection structures.

For S301 and S302, references may be made to the previous description about S101 and S102.

In one embodiment, as shown in FIG. 6, the redistribution layer may be formed on the plurality of blind holes 121 after being filled with conductive materials. That is, the redistribution layer may be formed on the front surfaces of the plurality of silicon wafters 120, and may be electrically connected to the plurality of blind holes 121 filled with conductive materials.

In one embodiment, the redistribution layer 122 may include a dielectric layer (not shown in the figure) and a metal layer (not shown in the figure) disposed on the dielectric layer. The dielectric layer may be formed on the surfaces of the plurality of silicon wafers 120 provided with the plurality of blind holes 121 by coating. The dielectric layer may be patterned using a lithography process, to form a plurality of openings on the passivation layer. And then, the metal layer may be formed on the patterned passivation layer by a process including sputtering or electroplating.

The dielectric layer may be made of a material including polyimide (PI), polybenzoxazole (PBO), etc., and the coating method may include heterogeneous chip spin coating, which is not limited in the present disclosure. The metal layer may be made of a material including titanium, copper, or other metal materials, which is not limited in the present disclosure.

In another embodiment, the redistribution layer 122 may be formed by: forming a photoresist layer on the surfaces of the plurality of silicon wafers 120 provided with the plurality of blind holes 121, patterning the photoresist layer to form a plurality of openings, and forming a thick metal layer on the plurality of openings, to form the redistribution layer 122.

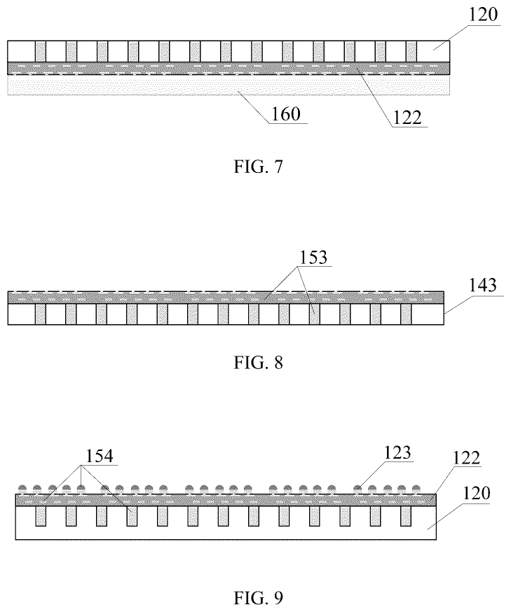

In one embodiment shown in FIG. 7, the redistribution layer 122 may be fixed on a temporary carrier board 160, and then the back surfaces of the plurality of silicon wafers 120 may be ground and polished to remove excess silicon materials the plurality of blind holes 121 are exposed. As shown in FIG. 8, the temporary carrier board 160 may be removed, to form the third conductive connection structures 153. That is, the third conductive connection structures 153 may include silicon through holes and the redistribution layer 122 disposed on the silicon through silicon holes.

As shown in FIG. 8, in the present embodiment, the third conductive connection structures 153 may be formed on the plurality of silicon wafers 120 to form the third silicon interposer plates 143. That is, the third silicon interposer plate 143 may be provided with silicon through holes and the redistribution layer 122 on the silicon through holes. The redistribution layer 122 may reorganize the signals led out by the silicon through holes and then lead out the signals of the third silicon interposer plate 143 as a whole.

In another embodiment shown in FIG. 2 to FIG. 10, S120 may include:

S401: forming a plurality of blind holes 121 on the front surface of at least one silicon wafer 120, where the plurality of blind holes 121 formed on the front surface of at least one silicon wafer 120 may be different from the plurality of blind holes 121 formed on the front surfaces of the remaining silicon wafers 120, as shown in FIG. 2;

S402: filling the plurality of blind holes 121 with conductive materials, as shown in FIG. 3;

S403: forming a redistribution layer 122 on the plurality of blind holes 121; and

S404: forming bumps on the redistribution layer 122; and

S405: thinning back surfaces of the plurality of silicon wafers until exposing the plurality of blind holes, to form the conductive connection structures.

For S401 and S402, references may be made to the previous description of $101 and S102. S403 may be similar to S303.

In one embodiment, as shown in FIG. 9, bump planting may be performed on the redistribution layer 122 to form the plurality of bumps 123.

In one embodiment, as shown in FIG. 10, the plurality of bumps 123 may be fixed on a temporary carrier board 160, and then the back surfaces of the plurality of silicon wafers 120 may be ground and polished to remove excess silicon materials the plurality of blind holes 121 are exposed. As shown in FIG. 11, the temporary carrier board 160 may be removed, to form the fourth conductive connection structures 154. That is, the fourth conductive connection structures 154 may include silicon through holes, the redistribution layer 122 disposed on the silicon through silicon holes, and the plurality of bumps 123 on the redistribution layer 122.

As shown in FIG. 11, in the present embodiment, the fourth conductive connection structures 154 may be formed on the plurality of silicon wafers 120 to form the fourth silicon interposer plates 144. That is, the fourth silicon interposer plate 144 may be provided with silicon through holes, the redistribution layer 122 on the silicon through holes, and the plurality of bumps 123 on the redistribution layer 122. The redistribution layer 122 and the plurality of bumps 123 on the redistribution layer 122 may reorganize the signals led out by the silicon through holes and then lead out the signals of the fourth silicon interposer plate 144 as a whole.

In other embodiments, other types of silicon interposer plates may be provided according to actual needs. The types of silicon interposer plates are not limited in the present disclosure.

In S130, each of the plurality of silicon interposer plates may be cut respectively to obtain a plurality of silicon interposer sub-plates.

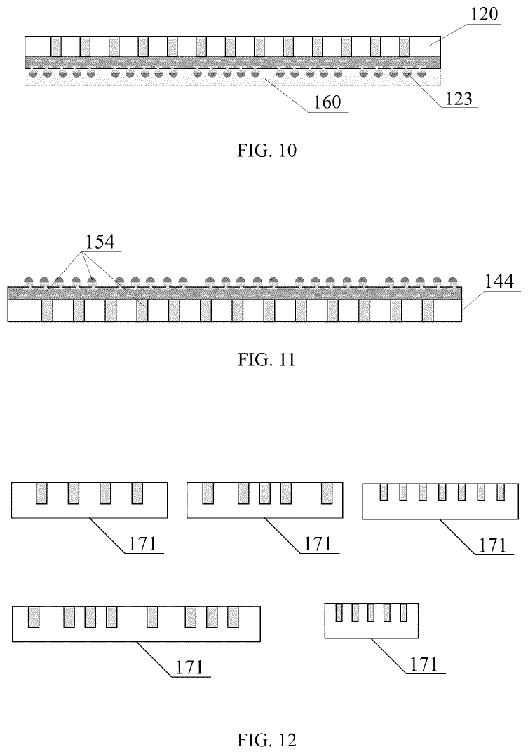

In one embodiment shown in FIG. 12 to FIG. 15, each of the plurality of silicon interposer plates may be cut respectively to obtain the plurality of silicon interposer sub-plates.

As shown in FIG. 11, in one embodiment, the first silicon interposer plates 141 may be cut and separated, to obtain a plurality of first silicon interposer sub-plates 171. Different silicon interposer sub-plates formed by cutting different silicon interposer plates may be different. For example, the first silicon interposer plates 141 with different structures may be cut and separated to form the plurality of first silicon interposer sub-plates 171, and the conductive connection structures on each of the plurality of first silicon interposer sub-plates 171 may have different density, width, or depth. Therefore, according to different packaging requirements, suitable first silicon interposer sub-plates 171 may be adopted for packaging based on the needs, improving the packaging integration levels.

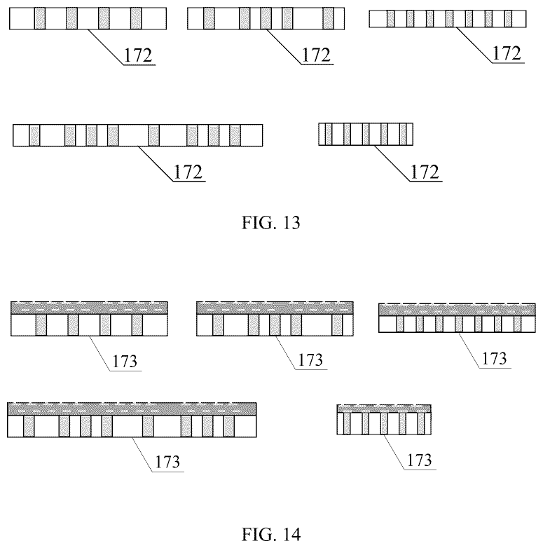

As shown in FIG. 13, in one embodiment, the second silicon interposer plates 142 may be cut and separated, to obtain a plurality of second silicon interposer sub-plates 172. Different silicon interposer sub-plates formed by cutting different silicon interposer plates may be different. For example, the second silicon interposer plates 142 with different structures may be cut and separated to form the plurality of second silicon interposer sub-plates 172, and the conductive connection structures on each of the plurality of second silicon interposer sub-plates 172 may have different density, width, or depth. Therefore, according to different packaging requirements, suitable second silicon interposer sub-plates 172 may be adopted for packaging based on the needs, improving the packaging integration levels.

As shown in FIG. 14, in one embodiment, the third silicon interposer plates 143 may be cut and separated, to obtain a plurality of third silicon interposer sub-plates 173. Different silicon interposer sub-plates formed by cutting different silicon interposer plates may be different. For example, the third silicon interposer plates 143 with different structures may be cut and separated to form the plurality of third silicon interposer sub-plates 173, and the conductive connection structures on each of the plurality of third silicon interposer sub-plates 173 may have different density, width, or depth. Therefore, according to different packaging requirements, suitable third silicon interposer sub-plates 173 may be adopted for packaging based on the needs, improving the packaging integration levels.

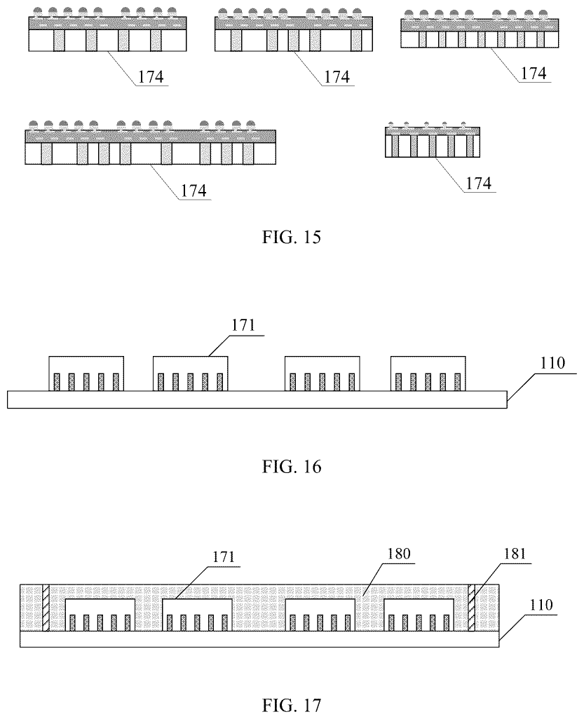

As shown in FIG. 15, in one embodiment, the fourth silicon interposer plates 144 may be cut and separated, to obtain a plurality of fourth silicon interposer sub-plates 174. Different silicon interposer sub-plates formed by cutting different silicon interposer plates may be different. For example, the fourth silicon interposer plates 144 with different structures may be cut and separated to form the plurality of fourth silicon interposer sub-plates 174, and the conductive connection structures on each of the plurality of fourth silicon interposer sub-plates 174 may have different density, width, or depth. Therefore, according to different packaging requirements, suitable fourth silicon interposer sub-plates 174 may be adopted for packaging based on the needs, improving the packaging integration levels.

In one embodiment, by cutting different silicon interposer plates obtained in the above steps, the plurality of silicon interposer sub-plates of various specifications may be obtained. The conductive connection structures, depth, width, or density of holes in each type of silicon interposer block may be different. Of course, the fourth types of silicon interposer sub-plates are used as examples to illustrate the present disclosure only and do not limit the scopes of the present disclosure. There may be other types of silicon interposer sub-plates.

The same type of silicon interposer sub-plates may also have conductive connection structures with different integration levels. For example, for first silicon interposer sub-plate sub-plates 171, the integration level of the conductive connection structures of each first silicon interposer sub-plate 171 may be different. For example, the density, width, depth, etc. of the conductive connection structures may be different.

In S140, a plurality of target silicon interposer sub-plates may be selected from the plurality of silicon interposer sub-plates according to preset packaging requirements, and the plurality of target silicon interposer sub-plates may be fixed on the carrier.

According to the preset packaging requirements, the plurality of target silicon interposer sub-plates may be selected from the plurality of silicon interposer sub-plates, and the plurality of target silicon interposer sub-plates may be fixed on the carrier 110. That is, according to different packaging requirements, the plurality of target silicon interposer sub-plates may be selected from the plurality of silicon interposer sub-plates. Then, the plurality of target silicon interposer sub-plates may be combined according to the packaging requirements, and then the plurality of target silicon interposer sub-plates may be fixed on the carrier 110.

In one embodiment, the plurality of target silicon interposer sub-plates may have the same height. Since the plurality of target silicon interposer sub-plates may have the same height, it may be unnecessarily to perform excessive polish on the plurality of target silicon interposer sub-plates, simplifying the packaging process and saving resources.

In some other embodiments, a height of at least one of the plurality of target silicon interposer sub-plates may be different from heights of remaining target silicon interposer sub-plates of the plurality of target silicon interposer sub-plates. The plurality of target silicon interposer sub-plates may be ground according to the packaging requirements to make the height consistent, and then the corresponding packaging steps may be performed. Or, different bonding structures may also be set to meet the high consistency of the plurality of target silicon interposer sub-plates.

In one embodiment, the front surfaces of the plurality of target silicon interposer sub-plates may be fixed to the carrier.

In another embodiment, the back surfaces of the plurality of target silicon interposer sub-plates may be fixed to the carrier.

In another embodiment, a first surface of at least one of the plurality of target silicon interposer sub-plates may be fixed to the carrier, and second surfaces of remaining target silicon interposer sub-plates of the plurality of target silicon interposer sub-plates may be fixed to the carrier. A first surface of one target silicon interposer sub-plate of the plurality of target silicon interposer sub-plates may be a front surface of the target silicon interposer sub-plate, and a second surface of one target silicon interposer sub-plate of the plurality of target silicon interposer sub-plates may be a back surface of the target silicon interposer sub-plate.

In one embodiment, selecting the plurality of target silicon interposer sub-plates from the plurality of silicon interposer sub-plates and fixing the front surfaces of the plurality of target silicon interposer sub-plates to the carrier board may include:

at least one of the plurality of target silicon interposer sub-plates have the conductive connection structure 150 different from the conductive connection structures 150 of other target silicon interposer sub-plates of the plurality of target silicon interposer sub-plates.

In the present embodiments, the conductive connection structure of at least one of the plurality of target silicon interposer sub-plates may be different from the conductive connection structures of other target silicon interposer sub-plates of the plurality of target silicon interposer sub-plates. Different target silicon interposer sub-plates may be selected for packaging according to the packaging requirements of different chips, to improve the packaging integration level when packaging the silicon interposer sub-plates with the plurality of chips and meet the packaging requirements of different chips.

The plurality of target silicon interposer sub-plates may be the same type of silicon interposer sub-plates or different types of silicon interposer sub-plates. That is, in this embodiment, the plurality of target silicon interposer sub-plates may be selected from one or more of the first silicon interposer sub-plates 171, the second silicon interposer sub-plates 172, the third silicon interposer sub-plates 173, or the fourth silicon interposer sub-plates 174 to be combined and then the front surfaces may be fixed on the carrier board 110. This present disclosure does not specifically limit the selection of the target silicon interposer sub-plates, and the selection may be made according to actual needs.

In one embodiment, the plurality of target silicon interposer sub-plates may be the same type of silicon interposer sub-plates, and the conductive connection structure 150 of at least one of the plurality of target silicon interposer sub-plates may be different from the conductive connection structures 150 of other target silicon interposer sub-plates of the plurality of target silicon interposer sub-plates. For example, the plurality of target silicon interposer sub-plates may be the first silicon interposer sub-plates 171, but the first conductive connection structures 151 in each first silicon interposer sub-plates 171 may be also different, such as the spacing, depth or width of the first conductive connection structures 151 may be different.

In the present disclosure, according to the preset packaging requirements, the plurality of target silicon interposer sub-plates may be selected from the plurality of silicon interposer sub-plates, and the plurality of target silicon interposer sub-plates may be fixed to the carrier board. Therefore, warping or cracking of the silicon interposers may be avoided when the plurality of chips is bonded to the plurality of target silicon interposer sub-plates. The conductive connection structures of at least one of the plurality of target silicon interposer sub-plates may be different from the conductive connection structures of others of the plurality of target silicon interposer sub-plates. The reorganized silicon interposer sub-plates may be formed with the plurality of chips at one time, thereby improving the integration level of chip packaging.

In one embodiment shown in FIG. 16, the plurality of target silicon interposer sub-plates may be fixed on the carrier by:

fixing front surfaces or back surfaces of the plurality of target silicon interposer sub-plates to the carrier; or

fixing a front surface of at least one of the plurality of target silicon interposer sub-plates to the carrier, and fixing back surfaces of remaining target silicon interposer sub-plates of the plurality of target silicon interposer sub-plates to the carrier.

In the present disclosure, there is no limit on the fixing direction of the plurality of target silicon interposer sub-plates which may be selected according to actual needs.

In one embodiment, as shown in FIG. 16, the plurality of first silicon interposer sub-plates 171 may be selected as the plurality of target silicon interposer sub-plates, and front surfaces of the plurality of first silicon interposer sub-plates 171 may be fixed to the carrier 110. As shown in FIG. 21, in another embodiment, back surfaces of the plurality of first silicon interposer sub-plates 171 may be fixed to the carrier 110. There is no limit on the fixing direction of the plurality of first silicon interposer sub-plates 171 which may be selected according to actual needs.

In another embodiment, the plurality of second silicon interposer sub-plates 172 may be selected as the plurality of target silicon interposer sub-plates, and front surfaces or back surfaces of the plurality of second silicon interposer sub-plates 172 may be fixed to the carrier 110.

In another embodiment, as shown in FIG. 25, the plurality of third silicon interposer sub-plates 173 may be selected as the plurality of target silicon interposer sub-plates, and front surfaces of the plurality of third silicon interposer sub-plates 173 may be fixed to the carrier 110. In another embodiment, front surfaces of the plurality of third silicon interposer sub-plates 173 may be fixed to the carrier 110. There is no limit on the fixing direction of the plurality of third silicon interposer sub-plates 173 which may be selected according to actual needs.

In another embodiment, as shown in FIG. 31, a combination of the plurality of second silicon interposer sub-plates 172 and the plurality of third silicon interposer sub-plates 173 may be selected as the plurality of target silicon interposer sub-plates. Front surfaces of the plurality of second silicon interposer sub-plates 172 and the plurality of third silicon interposer sub-plates 173 may be fixed to the carrier 110. In another embodiment, back surfaces of the plurality of second silicon interposer sub-plates 172 and the plurality of third silicon interposer sub-plates 173 may be fixed to the carrier 110. Fixing the front surfaces of the plurality of second silicon interposer sub-plates 172 and fixing the back surfaces of the plurality of second silicon interposer sub-plates 172 to the carrier may be the same, and it may be only needed to select the fixing direction of the plurality of third silicon interposer sub-plates 173. There is no limit on the fixing direction of the plurality of third silicon interposer sub-plates 173 which may be selected according to actual needs.

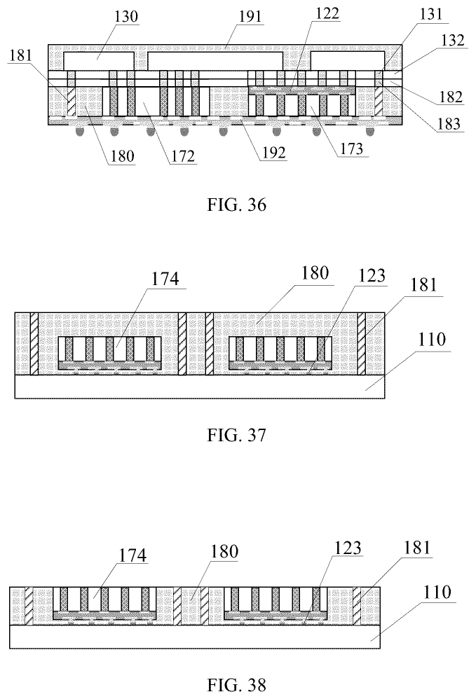

In another embodiment, as shown in FIG. 36, the plurality of fourth silicon interposer sub-plates 174 may be selected as the plurality of target silicon interposer sub-plates, and front surfaces of the plurality of fourth silicon interposer sub-plates 174 may be fixed to the carrier 110. In another embodiment, front surfaces of the plurality of fourth silicon interposer sub-plates 174 may be fixed to the carrier 110. There is no limit on the fixing direction of the plurality of fourth silicon interposer sub-plates 174 which may be selected according to actual needs.

In some other embodiments, other types of silicon interposer sub-plates may be selected and combined to form the plurality of target silicon interposer sub-plates, and then the plurality of target silicon interposer sub-plates may be fixed to the carrier. For example, in one embodiment, the second silicon interposer sub-plates 172 and the fourth silicon interposer sub-plates 174 may be selected and combined as the plurality of target silicon interposer sub-plates. The present disclosure has no limit on this.

In S150, a first plastic encapsulation layer may be formed on a side of the plurality of target silicon interposer sub-plates away from the carrier.

In one embodiment, the front surfaces of the plurality of target silicon interposer sub-plates may be fixed to the carrier and the first plastic encapsulation layer may be formed on the back surfaces of the plurality of target silicon interposer sub-plates.

In another embodiment, the back surfaces of the plurality of target silicon interposer sub-plates may be fixed to the carrier and the first plastic encapsulation layer may be formed on the front surfaces of the plurality of target silicon interposer sub-plates.

As shown in FIG. 17, FIG. 25, FIG. 31, and FIG. 36, after fixing the front surfaces of the plurality of target silicon interposer sub-plates on the carrier 110, the first plastic encapsulation layer 180 may be formed on the side of the plurality of target silicon interposer sub-plates way from the carrier 110. The first plastic encapsulation layer 180 may wrap the plurality of target silicon interposer sub-plates, to protect the plurality of target silicon interposer sub-plates. The first plastic encapsulation layer may be formed by a film vacuum lamination or an existing plastic encapsulation.

In one embodiment, as shown in FIG. 17, FIG. 25, FIG. 31, and FIG. 36, after forming the first plastic encapsulation layer 180 on the back surfaces of the plurality of target silicon interposer sub-plates, the method may further include:

forming a plurality of first through holes in the first plastic encapsulation layer 180 along its thickness direction, and filling the plurality of first through holes with conductive materials to form a plurality of first interconnection conductive pillars 181.

In one embodiment, before interconnecting the plurality of chips to the plurality of target silicon interposer sub-plates, the method may further include:

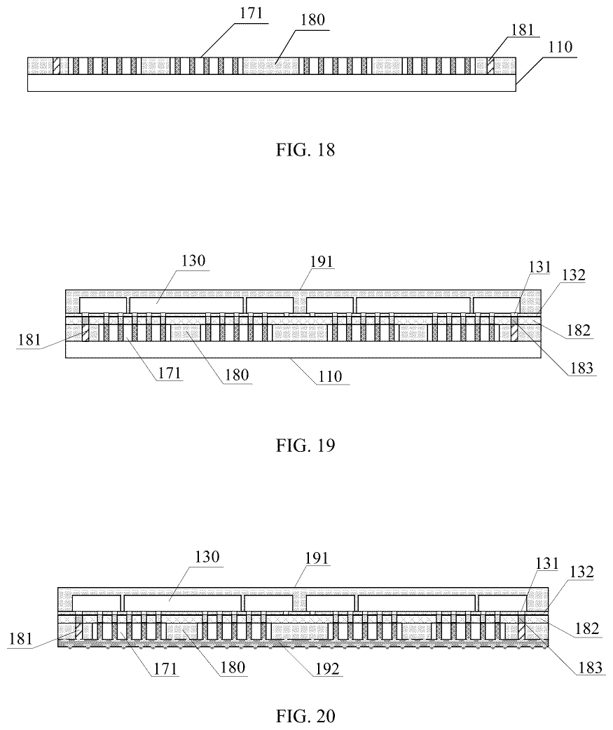

as shown in FIG. 18, FIG. 26, FIG. 32, and FIG. 37, thinning the side of the first plastic encapsulation layer 180 away from the carrier 110 to expose the conductive connection structures of the plurality of target silicon interposer sub-plates and the plurality of interconnection conductive pillars 181.

In the present embodiment, the side of the first plastic encapsulation layer 180 away from the carrier 110 may be thinned to expose the conductive connection structures of the plurality of target silicon interposer sub-plates and the plurality of interconnection conductive pillars 181, to prepare for interconnecting the plurality of chips to the plurality of target silicon interposer sub-plates.

In S160, the plurality of chips may be interconnected to the plurality of target silicon interposer sub-plates.

In one embodiment, interconnecting the plurality of chips 130 to the plurality of target silicon interposer sub-plates may include:

forming a second plastic encapsulation layer 191 on a side of the plurality of chips 130 away from the plurality of target silicon interposer sub-plates; and

removing the carrier 110, and interconnecting a side of the second plastic encapsulation layer 191 and the plurality of chips 130 facing the plurality of target silicon interposer sub-plates to front surfaces or back surfaces of the plurality of target silicon interposer sub-plates.

The plurality of chips 130 may be interconnected to the front surfaces or the back surfaces of the plurality of target silicon interposer sub-plates through a hybrid bonding process, a thermocompression bonding process, or a flip-chip process.

In one embodiment, the plurality of chips 130 may be the plurality of heterogeneous chips 130. Therefore, an appropriate process may be selected according to the types of the plurality of chips 139 and the types of the plurality of target silicon interposer sub-plates, to interconnect the plurality of heterogeneous chips 130 to the plurality of target silicon interposer sub-plates. The present disclosure has no limit on the interconnection process which may be selected according to actual needs.

As shown in FIG. 16 to FIG. 20, in one embodiment, a plurality of first silicon interposer sub-plates 171 may be selected as the plurality of target silicon interposer sub-plates. The plurality of first silicon interposer sub-plates may have same height. In one embodiment, the plurality of first silicon interposer sub-plates 171 may have the same structure. In some other embodiments, the plurality of first silicon interposer sub-plates 171 may have different structures, which may be selected according to actual needs. The bonding process for interconnecting the plurality of chips 130 to the back surfaces of the plurality of target silicon interposer sub-plates through the hybrid bonding structure may include the following processes.

As shown in FIG. 16, the plurality of first silicon interposer sub-plates 171 may be selected as the plurality of target silicon interposer sub-plates and the front surfaces of the plurality of first silicon interposer sub-plates 171 may be fixed to a carrier 110.

As shown in FIG. 17, the first plastic encapsulation layer 180 may be formed on the back surfaces of the plurality of first silicon interposer sub-plates 171. A plurality of first through holes may be formed in the first plastic encapsulation layer 180 along the thickness direction of the first plastic encapsulation layer 180, and the plurality of first through holes may be filled with conductive materials to form the plurality of first interconnection conductive pillars 181.

As shown in FIG. 18, the side of the first plastic encapsulation layer 180 away from the carrier 110 may be polished to expose the first conductive connection structures and the plurality of first interconnection conductive pillars 181 of the plurality of first silicon interposer sub-plates 171.

As shown in FIG. 19, the second plastic encapsulation layer 191 may be formed to encapsulate the plurality of chips 130, and a side of the second plastic encapsulation layer 191 facing the plurality of target silicon interposer sub-plates may be polished to expose the plurality of chips.

As shown in FIG. 19, the first metal pads 131 and the first passivation layer 132 may be sequentially formed on the side of the plurality of chips 130 and the second plastic encapsulation layer 191 facing the plurality of target silicon interposer sub-plates. In another embodiment, the first passivation layer 132 may be formed first and then may be patterned through lithography and etching processes. The first metal pads 131 may be formed on the patterned first passivation layer 132.

In one embodiment, the first passivation layer 132 may be made of a material including a silicon dioxide passivation layer, a silicon nitride layer, or other materials that could play a passivation role, which is not specifically limited in this embodiment. The first metal pad 131 may be made of a material including metal copper or other metal materials, which is not specifically limited in this embodiment.

As shown in FIG. 19, a second passivation layer 182 and second metal pads 183 may be sequentially formed on the sides of the plurality of first silicon interposer sub-plates 171 facing the plurality of chips 130. That is, the second passivation layer 182 and the second metal pads 183 may be sequentially formed on the back surfaces of the plurality of thinned first silicon interposer sub-plates 171.

In one embodiment, the second passivation layer 182 may be made of a silicon dioxide passivation layer or a silicon nitride layer, or other materials that could play a passivation role, which is not limited in this embodiment. The second metal pads 183 may be made of a material including metal copper or other metal materials, which is not limited in this embodiment.

As shown in FIG. 19, the first metal pads 131 and the second metal pads 183 may be bonded and connected, and the first passivation layer 132 and the second passivation layer 182 may be bonded and connected. The first metal pad 131 may also correspond to and be electrically connected to the plurality of first interconnection conductive pillars 181. Therefore, the plurality of chips 130 may be interconnected to the plurality of target silicon interposer sub-

As shown in FIG. 20, after the plurality of chips 130 are bonded to the front surfaces of the plurality of target silicon interposer sub-plates, the carrier 110 may be removed, and a first circuit layer 192 may be formed on sides of the plurality of first silicon interposer sub-plates 171 away from the plurality of chips 130. In one embodiment, the first circuit layer 192 may be formed on the front surfaces of the plurality of first silicon interposer sub-plates 171. In one embodiment, the first circuit layer 192 may electrically connect the packaging structure to the outside world. The first circuit layer 192 may include a redistribution layer and soldering balls, or may be a first circuit layer with other structures.

In this embodiment, the first interconnection circuit layer 192 may amplify the signals from the plurality of target silicon interposer sub-plates, improve the flexibility of packaging integration, and increase the interconnection density of the packaging structure.

In some other embodiments, after forming the first plastic encapsulation layer 180, the second passivation layer 182 and the second metal pads 183 may be formed on the front surfaces of the plurality of first silicon interposer sub-plates 171 after removing the carrier 110. The front surfaces of the plurality of first silicon interposer sub-plates 171 may be bond to the plurality of chips 130 through the second passivation layer 182 and the second metal pads 183. Subsequently, the back surfaces of the plurality of first silicon interposer sub-plates 171 may be thinned to expose the conductive connection structures and the first circuit layer 192 may be formed on the back surfaces of the plurality of thinned first silicon interposer sub-plates 171.

In some other embodiment, the plurality of first silicon interposer sub-plates 171 may be used as target silicon interposer sub-plates, and the back surfaces of the plurality of first silicon interposer sub-plates 171 may be fixed on the carrier 110. The plurality of chips 130 may be interconnected to the plurality of target silicon interposer sub-plates through a hybrid bonding process or a flip-chip process, and the reference may be made to the above embodiments and will not be described again here.

In one embodiment shown in FIG. 21, after the back surfaces of the plurality of first silicon interposer sub-plates 171 are fixed on the carrier 110 and the plurality of chips 130 are interconnected to the plurality of target silicon interposer sub-plates through a hybrid bonding process, the carrier 110 may be removed, and the side of the first plastic encapsulation layer 180 toward the carrier 110 may be thinned to expose the first conductive connection structures 151 of the plurality of first silicon interposer sub-plates 171. That is, the back surfaces of the plurality of first silicon interposer sub-plates 171 may be thinned, and then the first circuit layer 192 may be formed on the back surfaces of the plurality of thinned first silicon interposer sub-plates 171.

In one embodiment, after the plurality of chips 130 are interconnected to the front surfaces of the plurality of target silicon interposer sub-plates, the plurality of first through holes may be formed in the first plastic encapsulation layer 180 along the thickness direction of the first plastic encapsulation layer 180, and the plurality of first through holes may be filled with conductive materials to form the plurality of first interconnection conductive pillars 181.

As shown in FIG. 23, after thinning the back surfaces of the plurality of first silicon interposer sub-plates 171, the plurality of first through holes may be formed in the first plastic encapsulation layer 180 along the thickness direction of the first plastic encapsulation layer 180, and the plurality of first through holes may be filled with conductive materials to form the plurality of first interconnection conductive pillars 181. Two ends of the plurality of first interconnection conductive pillars 181 may be electrically connected to the plurality of chips 130 and the first interconnection circuit layer 192.

Usually the first interconnection conductive pillars 181 may be formed after the first plastic encapsulation layer 180 is formed, as shown in FIG. 17. Either process may be adopted to form the plurality of first through holes 181. In the present disclosure, preferably, the plurality of first through holes 181 may be formed after forming the first plastic encapsulation layer 180 on the back surfaces of the plurality of first silicon interposer sub-plates 171. The plurality of first through holes 181 may be used to realize the perpendicular electrical connection between the plurality of chips 130 and the first interconnection circuit layer 192, and may reduce the packaging height.

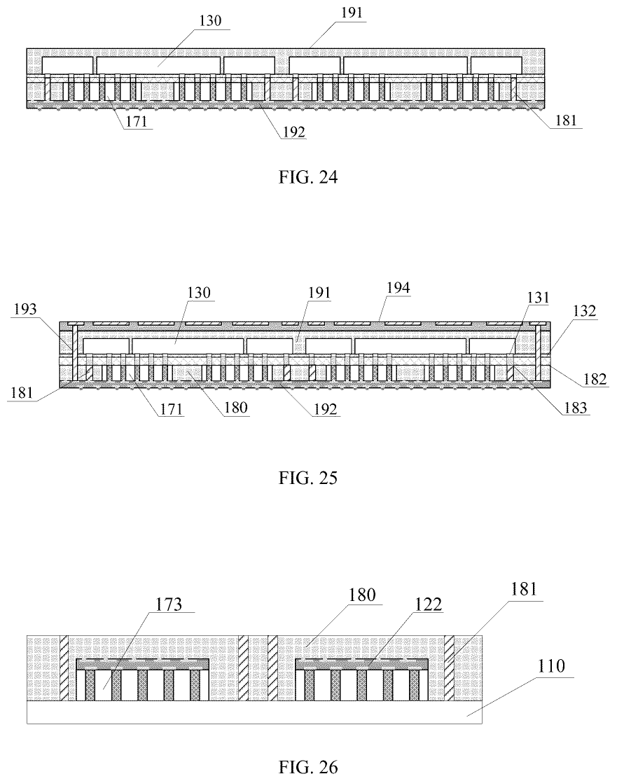

As shown in FIG. 24, the first circuit layer 192 may be formed on the first conductive connection structures exposed by the back surfaces of the plurality of thinned first silicon interposer sub-plates 171. In one embodiment, the first circuit layer 192 may electrically connect the packaging structure to the outside world. The first circuit layer 192 may include a redistribution layer and soldering balls, or may be a first circuit layer with other structures. In this embodiment, the first interconnection circuit layer 192 may amplify the signals from the plurality of target silicon interposer sub-plates, improve the flexibility of packaging integration, and increase the interconnection density of the packaging structure.

The plurality of chips may be interconnected to the plurality of target silicon interposer sub-plates through the hybrid bonding structure, to achieve a high-density interconnection and improve the production efficiency. Ultra-thin packaging may be achieved.

In another embodiment, the plurality of chips may be interconnected to the plurality of target silicon interposer sub-plates through a flip-chip process.

Plastic encapsulation may be performed on the plurality of chips 130 to form the second plastic encapsulation layer 191, and the side of the second plastic encapsulation layer 191 facing the plurality of target silicon interposer sub-plates to expose the plurality of chips 130. The first metal pads 131 may be formed on the side of the plurality of chips 130 facing the plurality of target silicon interposer sub-plates.

There may be no need to form the second passivation layer 182 and the second metal pad 183 on the plurality of first silicon interposer sub-plates 171 in the present embodiment. The plurality of chips 130 may be directly mounted on the back surfaces of the plurality of first silicon interposer sub-plates 171 through the first metal pads 131 using a flip-chip process. The first metal pads 131 may be electrically connected to the first conductive connection structures 151 and the first interconnection conductive pillars 181 exposed on the back surfaces of the plurality of first silicon interposer sub-plates 171. Further, an underfill may be formed on the first metal pads 131 to further fix the plurality of chips 130 on the plurality of target silicon interposer sub-plates. Of course, in some other embodiments, the plurality of chips 130 may be directly mounted on the back surfaces of the plurality of first silicon interposer sub-plates 171 through the first metal pads 131 using the flip-chip process, and the remaining bonding steps may remain unchanged.

In some other embodiments, in addition to interconnecting the plurality of chips to the plurality of target silicon interposer sub-plates through the hybrid bonding process or the flip-chip process, other processes may also be used, such as a thermocompression bonding process, etc., and there is no specific limitation in the present disclosure.

In some embodiments, the plurality of target silicon interposer sub-plates may be the plurality of second silicon interposer sub-plates 172, and the plurality of chips 130 may be interconnected to the plurality of target silicon interposer sub-plates through the hybrid bonding process or the flip-chip process. For the detail processes, reference may be made to the previous embodiments.

As shown in FIG. 25, in one embodiment, after forming the first circuit layer 192 on the sides of the plurality of target silicon interposer sub-plates away from the plurality of chips 130, the method may further include:

forming a plurality of second through holes in the thickness direction of the first plastic encapsulation layer 180 and the second plastic encapsulation layer 191, and filling the plurality of second through holes with conductive material to form a plurality of second interconnection conductive pillars 193. A second interconnection circuit layer 194 may be formed on a side of the second encapsulation layer 192 away from the plurality of target silicon interposer sub-plates. Two ends of each of the plurality of second interconnection conductive pillars 193 may be electrically connected to the first interconnection circuit layer 192 and the second interconnection circuit layer 194 respectively. The packaging of the plurality of chips 130 and the plurality of target silicon interposer sub-plates may be completed.

The plurality of second interconnection conductive pillars 193 may be used to realize vertical electrical interconnection between the packaging structure of the plurality of chips and other chips or modules, reducing the packaging height.

In one embodiment, the second interconnection circuit layer 194 may include a dielectric layer and a metal layer. The metal layer may be formed by electroplating or directly formed by patching. In one embodiment, the second interconnect circuit layer 194 may be a microstrip antenna radiating plate. Two ends of each of the plurality of second interconnection conductive pillars 193 may be electrically connected to the metal layer in the second interconnection circuit layer 194 and the metal layer in the redistribution layer of the first interconnection circuit layer 192 respectively. By forming the second interconnection circuit layer 194 on the side of the second plastic encapsulation layer 192 away from the plurality of target silicon interposer sub-plates, the signal of the entire packaging structure may be enhanced.

The packaging structure may include the second interconnection line layer, and communication heterogeneous chips or modules may be arranged on the second interconnection circuit layer after packaging. Compared with the existing processes where a metal layer and communication heterogeneous chips or modules are attached after the packaging the plurality of chips, the integration level of the chip packaging may be improved.

In another embodiment shown in FIG. 26 to FIG. 31, the plurality of target silicon interposer sub-plates may be the third silicon interposer sub-plates 173, and the plurality of chips 130 may be interconnected to the plurality of target silicon interposer sub-plates through the flip chip process.

As shown in FIG. 26, the plurality of third silicon interposer sub-plates 173 may be used as the plurality of target silicon interposer sub-plates, and the back surfaces of the plurality of third silicon interposer sub-plates 173 may be fixed on the carrier 110. The first plastic encapsulation layer 180 may be formed on the front surfaces of the plurality of third silicon interposer sub-plates 173. The plurality of first through holes may be formed in the first plastic encapsulation layer 180 along its thickness direction, and conductive materials may be filled in the plurality of first through holes to form the plurality of first interconnection conductive pillars 181.

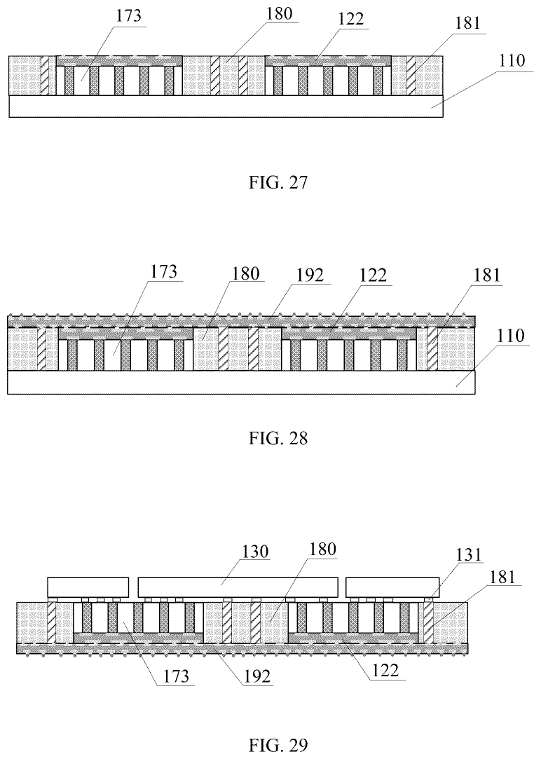

As shown in FIG. 27, the side of the first plastic encapsulation layer 180 away from the carrier 110 may be polished to expose the redistribution layer 122 of the plurality of third silicon interposer sub-plates 173 and the plurality of first interconnection conductive pillars

As shown in FIG. 28, the first circuit layer 192 may be formed on the redistribution layer 122 of the plurality of third silicon interposer sub-plates 173.

As shown in FIG. 29, the carrier 110 may be removed, and the plurality of chips 130 may be mounted on the back surfaces of the plurality of third silicon interposer sub-plates 173 through the first metal pads 131 using the flip-chip process. The first metal pads 131 may be electrically connected to the plurality of blind holes 121 filled with conductive material and the first interconnection conductive pillars 181 exposed on the back sides of the plurality of third silicon interposer sub-plates 173. Further, an underfill may be formed on the first metal pad 131 to further fix the plurality of chips 130 on the plurality of target silicon interposer sub-plates.

In another embodiment, as shown in FIG. 27, the side of the first plastic encapsulation layer 180 away from the carrier 110 may be ground to expose the redistribution layer 122 of the plurality of third silicon interposer sub-plates 173 and the plurality of first interconnection conductive pillars 181, the plurality of chips 130 may be mounted on the front surfaces of the plurality of third silicon interposer sub-plates 173 through the first metal pads 131 using the flip-chip process. That is, the plurality of chips 130 may be mounted on the redistribution layer 122 of the plurality of third silicon interposer sub-plates 173 through the first metal pads 131 using the flip-chip process. Further, an underfill may be formed on the first metal pads 131 to further fix the plurality of chips 130 on the plurality of target silicon interposer sub-plates.

As shown in FIG. 31, after the plurality of chips 130 are mounted on the redistribution layers 122 of the plurality of third silicon interposer sub-plates 173 through the first metal pads 131 using the flip-chip process, the first circuit layer 192 may be formed on the back surfaces of the plurality of third silicon interposer sub-plates 173. The first circuit layer 192 may include a redistribution layer and solder balls, which is not limited in this embodiment.

In some other embodiments, the plurality of chips 130 may be interconnected to the plurality of third silicon interposer sub-plates 173 through the hybrid bonding process. The specific hybrid bonding steps are similar to those in the previous embodiments. No further details will be given here.

In this embodiment, the plurality of chips may be interconnected to the plurality of target silicon interposer sub-plates through the flip-chip process, thereby reducing the packaging thickness and enabling ultra-thin packaging.

In another embodiment shown in FIG. 32 to FIG. 36, the plurality of target silicon interposer sub-plates may be a combination of a plurality of second silicon interposer sub-plates 172 and a plurality of third silicon interposer sub-plates 173. Therefore, bonding the plurality of chips 130 to the plurality of target silicon interposer sub-plates through a hybrid bonding process may include the following processes.

As shown in FIG. 32, the front surfaces of the plurality of second silicon interposer sub-plates 172 and the front surfaces of the plurality of third silicon interposer sub-plates 173 may be fixed to a carrier 110. The first plastic encapsulation layer 180 may be formed on the back surfaces of the plurality of second silicon interposer sub-plates 172 and the back surfaces of the plurality of third silicon interposer sub-plates 173. A plurality of through holes may be formed in the first plastic encapsulation layer 180 along the thickness direction of the first plastic encapsulation layer 180, and the plurality of first through holes may be filled with conductive materials to form the plurality of first interconnection conductive pillars 181.

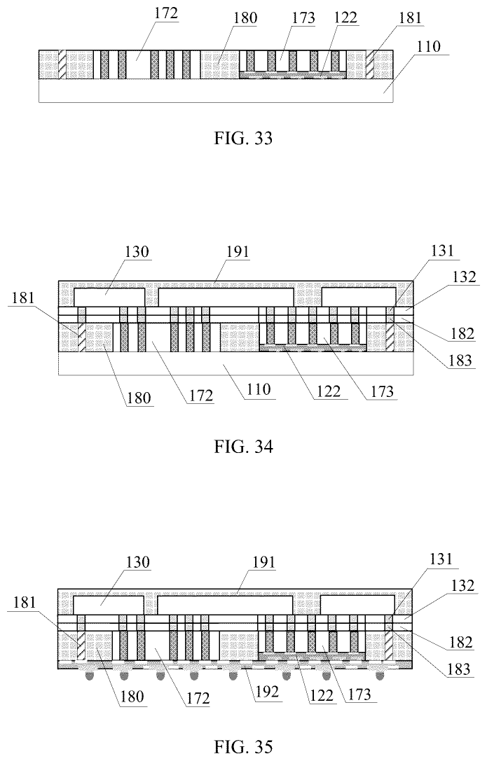

As shown in FIG. 33, a side of the first plastic encapsulation layer 180 away from the carrier 110 may be thinned by polishing to expose the conductive connection structures and the plurality of first interconnection conductive pillars 181 on the back surfaces of the plurality of second silicon interposer sub-plates 172 and the back surfaces of the plurality of third silicon interposer sub-plates 173.

As shown in FIG. 34, plastic encapsulation may be performed on the plurality of chips 130 to form a second plastic encapsulation layer 191. A side of the second plastic encapsulation layer 191 facing the plurality of target silicon interposer sub-plates may be polished to expose the plurality of chips. The first metal pads 131 and the first passivation layer 132 may be sequentially formed on a side of the plurality of chips and the second plastic encapsulation layer 191.

As shown in FIG. 34, the second passivation layer 182 and the second metal pads 183 may be sequentially formed on sides of the plurality of second silicon interposer sub-plates 172 and the plurality of third silicon interposer sub-plates 173 facing the plurality of chips 130.

That is, the second passivation layer 182 and the second metal pads 183 may be sequentially formed on the back surfaces of the thinned plurality of second silicon interposer sub-plates 172 and the back surfaces of the thinned plurality of third silicon interposer sub-plates 173.

As shown in FIG. 34, the first metal pads 131 and the second metal pads 183 may be bonded and connected, and the first passivation layer 132 and the second passivation layer 182 may be bonded and connected. The first metal pad 131 may also correspond to and be electrically connected to the first interconnection conductive pillars 181. Therefore, the plurality of chips 130 are bonded to the front surfaces of the plurality of target silicon interposer sub-

As shown in FIG. 35, after the plurality of chips 130 are bonded to the front surfaces of the plurality of target silicon interposer sub-plates, the carrier 110 may be removed, and then a first interconnection circuit layer 192 may be formed on the front surfaces of the plurality of second silicon interposer sub-plates 172 and the plurality of third silicon interposer sub-plates 173. The packaging structure may be electrically connected to the outside world through the first interconnection circuit layer 192. The first circuit layer 192 may include a redistribution layer and bumps, or may also include other circuit layers, which is not limited in this embodiment.

In another embodiment shown in FIG. 36, the back surfaces of the plurality of second silicon interposer sub-plates 172 and the plurality of third silicon interposer sub-plates 173 may be fixed on the carrier board 110. Then, the second passivation layer 182 and the second metal pads 183 may be formed on the front surfaces of the plurality of second silicon interposer sub-plates 172 and the plurality of third silicon interposer sub-plates 173. That is, the second passivation layer 182 and the second metal pads 183 may be formed on the through holes of the plurality of second silicon interposer sub-plates 172 and the redistribution layer 122 of the plurality of third silicon interposer sub-plates 173. The plurality of chips 130 may be interconnected to the front surfaces of the plurality of second silicon interposer sub-plates 172 and the plurality of third silicon interposer sub-plates 173 through the hybrid bonding process. Then the carrier board 110 may be removed, and the first circuit layer 192 may be formed on the back surface of the plurality of second silicon interposer sub-plates 172 and the plurality of third silicon interposer sub-plates 173.

In some other embodiments, the plurality of chips 130 may be also interconnected to the plurality of target silicon interposer sub-plates through the flip-chip process or the thermocompression bonding process.

In this embodiment, the plurality of chips may be bonded to the plurality of target silicon interposer sub-plates through the hybrid bonding process, thereby achieving high-density interconnection while improving production efficiency and achieving ultra-thin packaging.

In one embodiment, after forming the first interconnection circuit layer 192, as shown in FIG. 25, a plurality of second through holes may be formed in the thickness direction of the first plastic encapsulation layer 180 and the second plastic encapsulation layer 191. Conductive material may be filled in the plurality of second through holes to form a plurality of second interconnection conductive pillars 193. A second interconnection circuit layer 194 may be formed on a side of the second encapsulation layer 192 away from the plurality of target silicon interposer sub-plates. Two ends of each of the plurality of second interconnection conductive pillars 193 may be electrically connected to the first interconnection circuit layer 192 and the second interconnection circuit layer 194 respectively. The packaging of the plurality of chips 130 and the plurality of target silicon interposer sub-plates may be completed.

In another embodiment shown in FIG. 37 to FIG. 41, the plurality of target silicon interposer sub-plates may be the fourth silicon interposer sub-plates 174, and the plurality of chips 130 may be interconnected to the plurality of target silicon interposer sub-plates through the flip chip process.

As shown in FIG. 37, the plurality of fourth silicon interposer sub-plates 174 may be used as the plurality of target silicon interposer sub-plates, and the front surfaces of the plurality of fourth silicon interposer sub-plates 174 may be fixed on the carrier 110. The first plastic encapsulation layer 180 may be formed on the back surfaces of the plurality of fourth silicon interposer sub-plates 174. The plurality of first through holes may be formed in the first plastic encapsulation layer 180 along its thickness direction, and conductive materials may be filled in the plurality of first through holes to form the plurality of first interconnection conductive pillars 181.

As shown in FIG. 38, the side of the first plastic encapsulation layer 180 away from the carrier 110 may be thinned through a polish process to expose the conductive connection structures and the plurality of first interconnection conductive pillars 181 on the back surfaces of the plurality of fourth silicon interposer sub-plates 174.

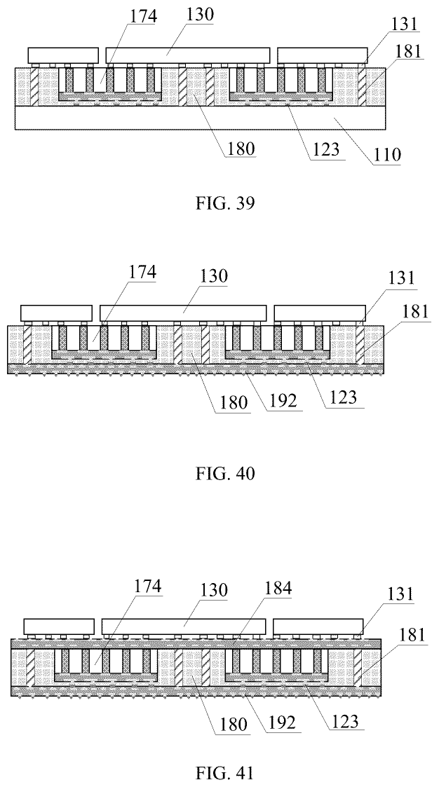

As shown in FIG. 39, the plurality of chips 130 may be mounted on the back surfaces of the plurality of fourth silicon interposer sub-plates 174 through the first metal pads 131 using the flip-chip process. The first metal pads 131 may be electrically connected to the conductive connection structures and the first interconnection conductive pillars 181 exposed on the back sides of the plurality of fourth silicon interposer sub-plates 174.

As shown in FIG. 40, the carrier 110 may be removed, and the first circuit layer 192 may be formed on the front surfaces of the plurality of fourth silicon interposer sub-plates 174. That is, the first circuit layer 192 may be formed on the soldering balls 123 of the plurality of fourth silicon interposer sub-plates 174. The first circuit layer 192 may include a redistribution layer and solder balls, which is not limited in this embodiment.

As shown in FIG. 41, after the side of the first plastic encapsulation layer 180 away from the carrier 110 is thinned through a polish process to expose the conductive connection structures and the plurality of first interconnection conductive pillars 181 on the back surfaces of the plurality of fourth silicon interposer sub-plates 174, an interconnection circuit layer 184 may be formed on the conductive connection structures and the first interconnection conductive pillars 181 on the back surfaces of the plurality of fourth silicon interposer sub-plates 174. Subsequently, the plurality chips 130 may be mounted on the interconnection circuit layer on the back surfaces of the plurality of fourth silicon interposer sub-plates 174 through the first metal pads 131 using the flip-chip process.

The plurality chips 130 may be interconnected to the plurality of fourth silicon interposer sub-plates 174 through the hybrid bonding process or the thermocompression bonding process.

In some other embodiments, the back surfaces of the plurality of fourth silicon interposer sub-plates 174 may be fixed to the carrier 110, and the plurality of chips 130 may be mounted on the soldering balls 123 on the front surfaces of the plurality of fourth silicon interposer sub-plates 174. The fixing direction of the plurality of fourth silicon interposer sub-plates 174 is not limited and may be selected according to actual needs.

In this embodiment, the plurality of chips may be interconnected to the plurality of target silicon interposer sub-plates through the flip-chip process, thereby reducing the packaging thickness and enabling ultra-thin packaging.

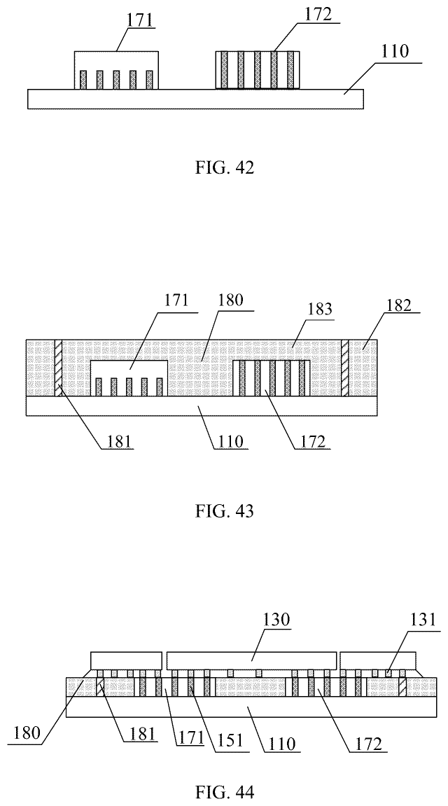

In one embodiment shown in FIG. 42 to FIG. 46, a plurality of first silicon interposer sub-plates 171 and a plurality of second silicon interposer sub-plates 172 may be selected as the plurality of target silicon interposer sub-plates. The plurality of first silicon interposer sub-plates 171 and the plurality of second silicon interposer sub-plates 172 may have same heights.

Correspondingly, bonding the plurality of chips 130 to the plurality of target silicon interposer sub-plates may include following processes/

As shown in FIG. 42, front surfaces of the plurality of first silicon interposer sub-plates 171 may be fixed on the carrier 110, and back surfaces of the plurality of second silicon interposer sub-plates 172 may be fixed on the carrier 110.

As shown in FIG. 43, a first plastic encapsulation layer 180 may be formed on the back surfaces of the plurality of first silicon interposer sub-plates 171 and the front surfaces of the plurality of second silicon interposer sub-plates 172. A plurality of first through holes are formed in the first plastic encapsulation layer 180 along its thickness direction, and conductive materials may be filled in the plurality of first through holes to form a plurality of first interconnection conductive pillars 181.

As shown in FIG. 44, a side of the first plastic encapsulation layer 180 away from the carrier 110 may be thinned through a grinding process to expose the first conductive connection structure 151 on the back surfaces of the plurality of first silicon interposer sub-plates 171 and the second conductive connection structures 152 on the front surfaces of the plurality of second silicon interposer sub-plates 172 and the plurality of first interconnection conductive pillars 181. That is, the plurality of silicon through holes on the back surfaces of the plurality of first silicon interposer sub-plates 171 and the plurality of silicon through holes on the back surfaces of the plurality of second silicon interposer sub-plates 172 may be exposed.

As shown in FIG. 44, a plurality of first metal pads 131 may be formed on the side of the plurality of chips 130 facing the plurality of first silicon interposer sub-plates 171, and the plurality of chips 130 may be mounted on the back surfaces of the plurality of first silicon interposer sub-plates 171 and the front surfaces of the plurality of second silicon interposer sub-plates 172 through the plurality of first metal pads 131. The plurality of first metal pads 131 may correspond to and may be electrically connected to the plurality of silicon through holes on the back surfaces of the plurality of first silicon interposer sub-plates 171 and the front surfaces of the plurality of second silicon interposer sub-plates 172. That is, in this embodiment, the bonding structure may include the plurality of first metal pads 131 formed on the side of the plurality of chips 130 toward the plurality of first silicon interposer sub-plates 171 and the plurality of second silicon interposer sub-plates 172. Further, an underfill may be formed on the plurality of first metal pads 131 to further fix the plurality of chips 130 on the plurality of target silicon interposer sub-plates. The plurality of first metal pads 131 may be made of a material including metal copper or other metal materials, which is not limited in this embodiment.

As shown in FIG. 46, after the plurality of chips 130 is mounted on the back surfaces of the plurality of first silicon interposer sub-plates 171 and the front surfaces of the plurality of second silicon interposer sub-plates 172 through the flip-chip process, the carrier 110 may be removed. The first circuit layer 192 may be formed on the front surfaces of the plurality of first silicon interposer sub-plates 171 and the back surfaces of the plurality of second silicon interposer sub-plates 172. The package structure may be electrically connected to the outside world through the first circuit layer 192. The first circuit layer 192 may include a redistribution layer and solder balls, or may include other circuit layers. This embodiment is not limited.

As shown in FIG. 42 to FIG. 46, in another embodiment, a plurality of first silicon interposer sub-plates 171 and a plurality of second silicon interposer sub-plates 172 may be selected as the plurality of target silicon interposer sub-plates. The plurality of first silicon interposer sub-plates 171 and the plurality of second silicon interposer sub-plates 172 may have same heights.

Correspondingly, bonding the plurality of chips 130 to the plurality of target silicon interposer sub-plates may include following processes/

As shown in FIG. 42, front surfaces of the plurality of first silicon interposer sub-plates 171 may be fixed on the carrier 110, and back surfaces of the plurality of second silicon interposer sub-plates 172 may be fixed on the carrier 110.

As shown in FIG. 43, a first plastic encapsulation layer 180 may be formed on the back surfaces of the plurality of first silicon interposer sub-plates 171 and the front surfaces of the plurality of second silicon interposer sub-plates 172. A plurality of first through holes are formed in the first plastic encapsulation layer 180 along its thickness direction, and conductive materials may be filled in the plurality of first through holes to form a plurality of first interconnection conductive pillars 181.

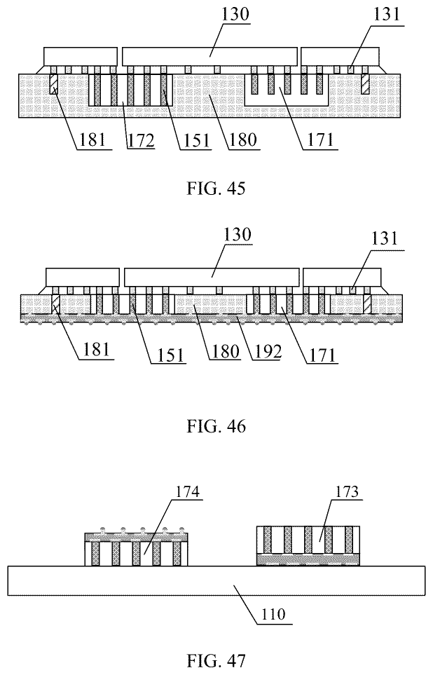

As shown in FIG. 45, the carrier 110 may be removed, and a plurality of first metal pads 131 may be formed on the side of the plurality of chips 130 facing the plurality of first silicon interposer sub-plates 171. The plurality of chips 130 may be mounted on the back surfaces of the plurality of first silicon interposer sub-plates 171 and the front surfaces of the plurality of second silicon interposer sub-plates 172 through the plurality of first metal pads 131 using the flip-chip process. The plurality of first metal pads 131 may correspond to and may be electrically connected to the plurality of silicon through holes on the back surfaces of the plurality of first silicon interposer sub-plates 171 and the front surfaces of the plurality of second silicon interposer sub-plates 172. Further, an underfill may be formed on the plurality of first metal pads 131 to further fix the plurality of chips 130 on the plurality of target silicon interposer sub-plates. The plurality of first metal pads 131 may be made of a material including metal copper or other metal materials, which is not limited in this embodiment.

As shown in FIG. 46, a side of the first plastic encapsulation layer 180 away from the plurality of chips 130 may be thinned through a grinding process to expose the first conductive connection structure 151 on the back surfaces of the plurality of first silicon interposer sub-plates 171 and the second conductive connection structures 152 on the front surfaces of the plurality of second silicon interposer sub-plates 172 and the plurality of first interconnection conductive pillars 181. The back surfaces of the plurality of first silicon interposer sub-plates 171 and the front surfaces of the plurality of second silicon interposer sub-plates 172 may be flush. The first circuit layer 192 may be formed on the front surfaces of the plurality of first silicon interposer sub-plates 171 and the back surfaces of the plurality of second silicon interposer sub-plates 172. The package structure may be electrically connected to the outside world through the first circuit layer 192. The first circuit layer 192 may include a redistribution layer and solder balls, or may include other circuit layers. This embodiment is not limited.

As shown in 47 to FIG. 49, in another embodiment, a plurality of third silicon interposer sub-plates 173 and a plurality of fourth silicon interposer sub-plates 174 may be selected as the plurality of target silicon interposer sub-plates. The plurality of third silicon interposer sub-plates 173 and the plurality of fourth silicon interposer sub-plates 174 may have same heights.

Correspondingly, bonding the plurality of chips 130 to the plurality of target silicon interposer sub-plates may include following processes/

As shown in FIG. 47, front surfaces of the plurality of third silicon interposer sub-plates 173 may be fixed on the carrier 110, and back surfaces of the plurality of fourth silicon interposer sub-plates 174 may be fixed on the carrier 110.

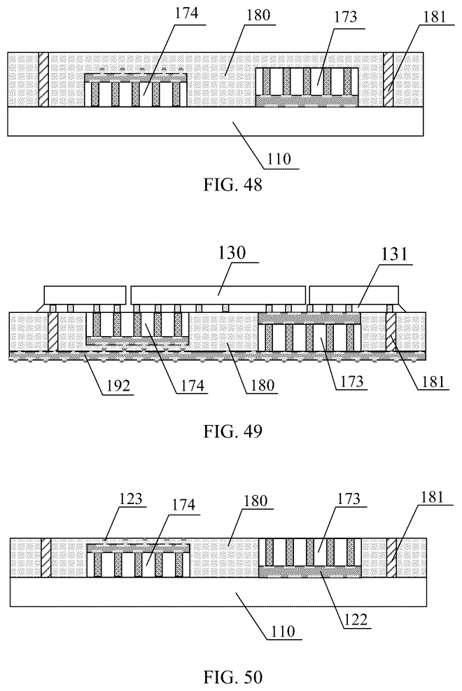

As shown in FIG. 48, a first plastic encapsulation layer 180 may be formed on the back surfaces of the plurality of third silicon interposer sub-plates 173 and the front surfaces of the plurality of fourth silicon interposer sub-plates 174. A plurality of first through holes are formed in the first plastic encapsulation layer 180 along its thickness direction, and conductive materials may be filled in the plurality of first through holes to form a plurality of first interconnection conductive pillars 181.

As shown in FIG. 49, the carrier 110 may be removed to expose the redistribution layer 122 on the front surfaces of the plurality of third silicon interposer sub-plates 173 and the plurality of silicon through holes on the back surfaces of the plurality of fourth silicon interposer sub-plates 174.

As shown in FIG. 49, a plurality of first metal pads 131 may be formed on the side of the plurality of chips 130 facing the plurality of third silicon interposer sub-plates 173 and the plurality of fourth silicon interposer sub-plates 174. The plurality of chips 130 may be mounted on the front surfaces of the plurality of third silicon interposer sub-plates 173 and the back surfaces of the plurality of fourth silicon interposer sub-plates 174 through the plurality of first metal pads 131 using the flip-chip process.

As shown in FIG. 49, a first circuit layer 192 may be formed on the back surfaces of the plurality of third silicon interposer sub-plates 173 and the front surfaces of the plurality of fourth silicon interposer sub-plates 174.

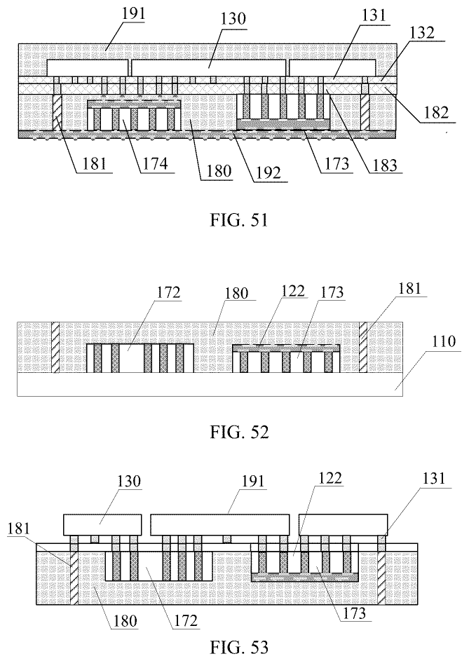

In another embodiment shown in FIG. 50 and FIG. 51, a plurality of third silicon interposer sub-plates 173 and a plurality of fourth silicon interposer sub-plates 174 may be selected as the plurality of target silicon interposer sub-plates. The plurality of third silicon interposer sub-plates 173 and the plurality of fourth silicon interposer sub-plates 174 may have same heights.

Correspondingly, bonding the plurality of chips 130 to the plurality of target silicon interposer sub-plates may include following processes.

As shown in FIG. 50, front surfaces of the plurality of third silicon interposer sub-plates 173 may be fixed on the carrier 110, and back surfaces of the plurality of fourth silicon interposer sub-plates 174 may be fixed on the carrier 110.

As shown in FIG. 50, a first plastic encapsulation layer 180 may be formed on the back surfaces of the plurality of third silicon interposer sub-plates 173 and the front surfaces of the plurality of fourth silicon interposer sub-plates 174. A plurality of first through holes are formed in the first plastic encapsulation layer 180 along its thickness direction, and conductive materials may be filled in the plurality of first through holes to form a plurality of first interconnection conductive pillars 181.

As shown in FIG. 50, a side of the first plastic encapsulation layer 180 away from the plurality of chips 130 may be thinned to expose the plurality of silicon through holes on the back surfaces of the plurality of third silicon interposer sub-plates 173 and the plurality of soldering balls on the front surfaces of the plurality of fourth silicon interposer sub-plates 174.

As shown in FIG. 51, a second plastic encapsulation layer 191 may be formed on a side of the plurality of chips away from the plurality of target silicon interposer sub-plates. A first metal pads 131 and the first passivation layer 132 may be formed on the side of the plurality of chips 130 and the second plastic encapsulation layer 191 facing the plurality of target silicon interposer sup-plates.

As shown in FIG. 51, the second passivation layer 182 and the second metal pads 183 may be formed on the back surfaces of the plurality of third silicon interposer sup-plates 173, the front surfaces of the plurality of fourth silicon interposer sup-plates 174, and the surface of the first plastic encapsulation layer 180.

As shown in FIG. 51, the first metal pads 131 and the second metal pads 183 may be bonded and connected, and the first passivation layer 132 and the second passivation layer 182 may be bonded and connected. The first metal pad s131 may also correspond to and may be electrically connected to the first interconnection conductive pillars 181. Therefore, the plurality of chips 130 may be bonded to the plurality of third silicon interposer sub-plates 173 and the plurality of fourth silicon interposer sub-plates 174.

As shown in FIG. 51, the carrier 110 may be removed, and a first circuit layer 192 may be formed on the front surfaces of the plurality of third silicon interposer sub-plates 173 and the back surface of the plurality of fourth silicon interposer sub-plates 174.

In some other embodiments, the back surfaces of the plurality of third silicon interposer sub-plates 173 and the front surfaces of the plurality of fourth silicon interposer sub-plates 174 may be fixed on the carrier 110, and the selection can be made according to actual needs.

In another embodiment shown in FIG. 52 to FIG. 54, a plurality of second silicon interposer sub-plates 172 and a plurality of third silicon interposer sub-plates 173 may be selected as the plurality of target silicon interposer sub-plates. The plurality of second silicon interposer sub-plates 172 and the plurality of third silicon interposer sub-plates 173 may have same heights.

Correspondingly, bonding the plurality of chips 130 to the plurality of target silicon interposer sub-plates may include following processes/

As shown in FIG. 52, front surfaces of the plurality of second silicon interposer sub-plates 172 may be fixed on the carrier 110, and back surfaces of the plurality of third silicon interposer sub-plates 173 may be fixed on the carrier 110. A first plastic encapsulation layer 180 may be formed on the back surfaces of the plurality of second silicon interposer sub-plates 172 and the front surfaces of the plurality of third silicon interposer sub-plates 173. A plurality of first through holes are formed in the first plastic encapsulation layer 180 along its thickness direction, and conductive materials may be filled in the plurality of first through holes to form a plurality of first interconnection conductive pillars 181.

As shown in FIG. 53, the carrier 110 may be removed. A plurality of first metal pads 131 may be formed on the side of the plurality of chips 130 facing the plurality of second silicon interposer sub-plates 172, and the plurality of chips 130 may be mounted on the back surfaces of the plurality of second silicon interposer sub-plates 172 and the front surfaces of the plurality of third silicon interposer sub-plates 173 through the plurality of first metal pads 131. The plurality of first metal pads 131 may correspond to and may be electrically connected to the plurality of silicon through holes on the front surfaces of the plurality of second silicon interposer sub-plates 172 and the back surfaces of the plurality of third silicon interposer sub-plates 173.

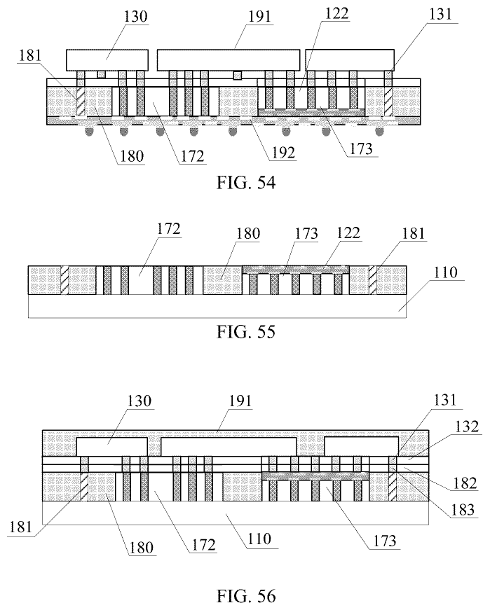

As shown in FIG. 54, a side of the first plastic encapsulation layer 180 away from the carrier 110 may be thinned through a grinding process to expose the first conductive connection structure 151 on the back surfaces of the plurality of second silicon interposer sub-plates 172 and the second conductive connection structures 152 on the front surfaces of the plurality of third silicon interposer sub-plates 173. That is, the silicon through holes on the back surfaces of the plurality of second silicon interposer sub-plates 172 and the redistribution layer 122 on the front surfaces of the plurality of third silicon interposer sub-plates 173 may be exposed. The first circuit layer 192 may be formed on the back surfaces of the plurality of first silicon interposer sub-plates 171 and the front surfaces of the plurality of second silicon interposer sub-plates 172. The package structure may be electrically connected to the outside world through the first circuit layer 192. The first circuit layer 192 may include a redistribution layer and solder balls, or may include other circuit layers. This embodiment is not limited.

In another embodiment shown in FIG. 55 to FIG. 57, a plurality of second silicon interposer sub-plates 172 and a plurality of third silicon interposer sub-plates 173 may be selected as the plurality of target silicon interposer sub-plates. The plurality of second silicon interposer sub-plates 172 and the plurality of third silicon interposer sub-plates 173 may have same heights.

Correspondingly, bonding the plurality of chips 130 to the plurality of target silicon interposer sub-plates may include following processes/

As shown in FIG. 55, front surfaces of the plurality of second silicon interposer sub-plates 172 may be fixed on the carrier 110, and back surfaces of the plurality of third silicon interposer sub-plates 173 may be fixed on the carrier 110. A first plastic encapsulation layer 180 may be formed on the back surfaces of the plurality of second silicon interposer sub-plates 172 and the front surfaces of the plurality of third silicon interposer sub-plates 173. A plurality of first through holes are formed in the first plastic encapsulation layer 180 along its thickness direction, and conductive materials may be filled in the plurality of first through holes to form a plurality of first interconnection conductive pillars 181.

As shown in FIG. 55, a side of the first plastic encapsulation layer 180 away from the carrier 110 may be thinned through a grinding process to expose the first conductive connection structure 151 on the back surfaces of the plurality of second silicon interposer sub-plates 172, the second conductive connection structures 152 on the front surfaces of the plurality of third silicon interposer sub-plates 173, and the first interconnection conductive pillars 181.

As shown in FIG. 56, a second plastic encapsulation layer 191 may be formed on a side of the plurality of chips away from the plurality of target silicon interposer sub-plates. The first metal pads 131 and the first passivation layer 132 may be formed on the side of the plurality of chips 130 and the second plastic encapsulation layer 191 facing the plurality of target silicon interposer sup-plates. The second passivation layer 182 and the second metal pads 183 may be formed on the back surfaces of the plurality of third silicon interposer sup-plates 173, the front surfaces of the plurality of fourth silicon interposer sup-plates 174, and the surface of the first plastic encapsulation layer 180.

As shown in FIG. 56, the first metal pads 131 and the second metal pads 183 may be bonded and connected, and the first passivation layer 132 and the second passivation layer 182 may be bonded and connected. The first metal pad s131 may also correspond to and may be electrically connected to the first interconnection conductive pillars 181. Therefore, the plurality of chips 130 may be bonded to the plurality of third silicon interposer sub-plates 173 and the plurality of fourth silicon interposer sub-plates 174 through the hybrid bonding process.

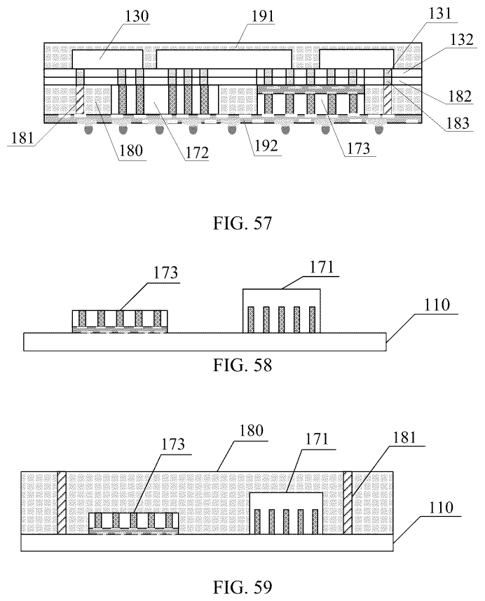

As shown in FIG. 57, the carrier 110 may be removed, and a first circuit layer 192 may be formed on the front surfaces of the plurality of third silicon interposer sub-plates 173 and the back surface of the plurality of fourth silicon interposer sub-plates 174.

In some other embodiments, the front surfaces of the plurality of third silicon interposer sub-plates 173 and the back surfaces of the plurality of second silicon interposer sub-plates 172 may be fixed on the carrier 110, and the selection can be made according to actual needs.

In some other embodiments, the height of at least one target silicon interposer sub-plate may be lower than the heights of other target silicon interposer sub-plates among the plurality of target silicon interposer sub-plates.

Correspondingly, bonding the plurality of chips to the plurality of target silicon interposer sub-plates may include:

forming the second plastic encapsulation layer on the side of the plurality of chips away from the plurality of target silicon interposer sub-plates; and

removing the carrier 110 and bonding the side of the plurality of chips and the second plastic encapsulation layer facing the plurality of target silicon interposer sub-plates to the front surfaces of the plurality of target silicon interposer sub-plates.

For example, in one embodiment as shown in FIG. 58 to FIG. 63, a plurality of first silicon interposer sub-plates 171 and a plurality of third silicon interposer sub-plates 173 may be selected as the plurality of target silicon interposer sub-plates. The plurality of third silicon interposer sub-plates 173 may have a height lower than the height of the plurality of first silicon interposer sub-plates 171.

As shown in FIG. 58, the front surfaces of the plurality of first silicon interposer sub-plates 171 and the plurality of third silicon interposer sub-plates 173 may be fixed to a carrier 110.

As shown in FIG. 59, the first plastic encapsulation layer 180 may be formed on the back surfaces of the plurality of first silicon interposer sub-plates 171 and the plurality of third silicon interposer sub-plates 173. A plurality of first through holes may be formed in the first plastic encapsulation layer 180 along the thickness direction of the first plastic encapsulation layer 180, and the plurality of first through holes may be filled with conductive materials to form the plurality of first interconnection conductive pillars 181.

As shown in FIG. 61, the second plastic encapsulation layer 191 may be formed to encapsulate on the side of the plurality of chips 130 away from the plurality of target silicon interposer sub-plates.

As shown in FIG. 61, the first metal pads 131 and the first passivation layer 132 may be sequentially formed on the side of the plurality of chips 130 and the second plastic encapsulation layer 191 facing the plurality of target silicon interposer sub-plates. The first passivation layer 132 may be made of a material including a silicon dioxide passivation layer, a silicon nitride layer, or other materials that could play a passivation role, which is not limited in this embodiment. The first metal pad 131 may be made of a material including metal copper or other metal materials, which is not limited in this embodiment.

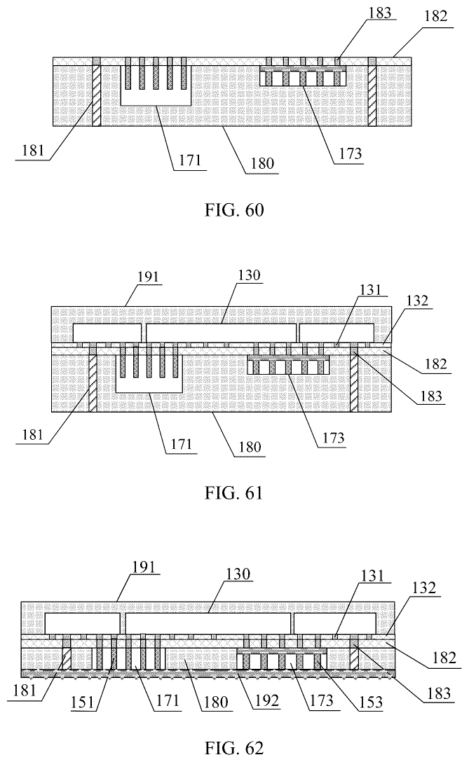

As shown in FIG. 60, the carrier 110 may be removed. a second passivation layer 182 and second metal pads 183 may be sequentially formed on the sides of the plurality of first silicon interposer sub-plates 171 and the plurality of third silicon interposer sub-plates 173 facing the plurality of chips 130. In some other embodiments, the second metal pads 183 may be formed before forming the second passivation layer 182.

In one embodiment, the second passivation layer 182 may be made of a silicon dioxide passivation layer or a silicon nitride layer, or other materials that could play a passivation role, which is not limited in this embodiment. The second metal pads 183 may be made of a material including metal copper or other metal materials, which is not limited in this embodiment.

As shown in FIG. 61, the side of the plurality of chips 130 and the second plastic encapsulation layer 191 facing the plurality of target silicon interposer sub-plates may be bonded to the front surfaces of plurality of target silicon interposer sub-plates. The first metal pads 131 and the second metal pads 183 may be bonded and connected, and the first passivation layer 132 and the second passivation layer 182 may be bonded and connected. The first metal pad 131 may also correspond to and be electrically connected to the plurality of first interconnection conductive pillars 181. Therefore, the plurality of chips 130 may be interconnected to the plurality of target silicon interposer sub-plates.

As shown in FIG. 62, a side of the first plastic encapsulation layer 180 away from the plurality of chips 130 may be thinned to expose the conductive connection structures on the back surfaces of the plurality of target silicon interposer sub-plates. That is, the side of the first plastic encapsulation layer 180 away from the plurality of chips 130 may be thinned to expose the first conductive connection structures 151 on the back surfaces of the plurality of first silicon interposer sub-plates 171 and the third conductive connection structures 153 on the back surfaces of the plurality of third silicon interposer sub-plates 173.

After thinning, the back surface of target silicon interposer with the lower height may be flush with the back surfaces of other target silicon interposers. That is, the back surfaces of the plurality of first silicon interposer sub-plates 171 may need to be thinned to be flush with the height of the plurality of third silicon interposer sub-plates 173 to prepare for subsequent packaging.

The first circuit layer 192 may be formed on the back surfaces of the plurality of target silicon interposer sub-plates 172. The package structure may be electrically connected to the outside world through the first circuit layer 192. The first circuit layer 192 may include a redistribution layer and solder balls, or may include other circuit layers. This embodiment is not limited.

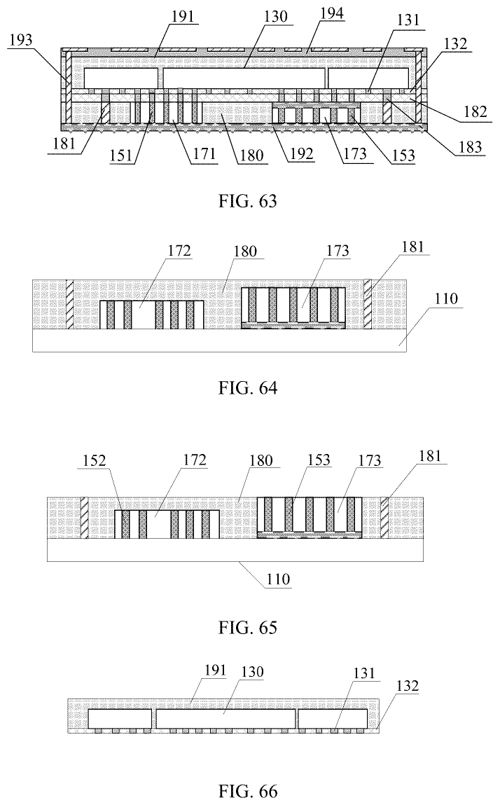

As shown in FIG. 63, the method may further include: forming a plurality of second through holes in the thickness direction of the first plastic encapsulation layer 180 and the second plastic encapsulation layer 191, and filling the plurality of second through holes with conductive material to form a plurality of second interconnection conductive pillars 193. A second circuit layer 194 may be formed on a side of the second encapsulation layer 192 away from the plurality of target silicon interposer sub-plates. Two ends of each of the plurality of second interconnection conductive pillars 193 may be electrically connected to the first interconnection circuit layer 192 and the second interconnection circuit layer 194 respectively. The packaging of the plurality of chips 130 and the plurality of target silicon interposer sub-plates may be completed.

In another embodiment shown in FIG. 64 to FIG. 69, a plurality of second silicon interposer sub-plates 172 and a plurality of third silicon interposer sub-plates 173 may be selected as the plurality of target silicon interposer sub-plates. The plurality of third silicon interposer sub-plates 173 may have a height higher than the height of the plurality of second silicon interposer sub-plates 172.

As shown in FIG. 65, the first plastic encapsulation layer 180 may be formed on the back surfaces of the plurality of second silicon interposer sub-plates 172 and the plurality of third silicon interposer sub-plates 173. A plurality of first through holes may be formed in the first plastic encapsulation layer 180 along the thickness direction of the first plastic encapsulation layer 180, and the plurality of first through holes may be filled with conductive materials to form the plurality of first interconnection conductive pillars 181.

As shown in FIG. 69, a second plastic encapsulation layer 191 may be formed on a side of the plurality of chips 130 away from the plurality of target silicon interposer sub-plates.

As shown in FIG. 66, a side of the first plastic encapsulation layer 180 away from the plurality of target silicon interposer sub-plates may be thinned to expose the conductive connection structures on the back surfaces of target silicon interposer sub-plates with a higher height among the plurality of target silicon interposer sub-plates. That is, the side of the first plastic encapsulation layer 180 away from the plurality of target silicon interposer sub-plates may be thinned to expose the third conductive connection structures 153 on the back surfaces of the plurality of third silicon interposer sub-plates 173. The back surfaces of the plurality of second silicon interposer sub-plates 172 may still be wrapped by the first plastic encapsulation layer 180.

The side of the plurality of chips 130 and the second plastic encapsulation layer 191 facing the plurality of target silicon interposer sub-plates may be bonded to the back surfaces of target silicon interposer sub-plates with lower heights among the plurality of thinned target silicon interposer sub-plates through a first bonding structure.

The side of the plurality of chips 130 and the second plastic encapsulation layer 191 facing the plurality of target silicon interposer sub-plates may be bonded to the back surfaces of target silicon interposer sub-plates with higher heights among the plurality of thinned target silicon interposer sub-plates through a second bonding structure.

A height of the first bonding structure may be larger than a height of the second bonding structure.

As shown in FIG. 66, the first metal pads 131 and the first passivation layer 132 may be sequentially formed on the side of the plurality of chips 130 and the second plastic encapsulation layer 191 facing the plurality of target silicon interposer sub-plates. The first metal pads 131 corresponding to the plurality of second silicon interposer sub-plates 172 may have a height consistent with a height of the first metal pads corresponding to the plurality of third silicon interposer sub-plates 173.

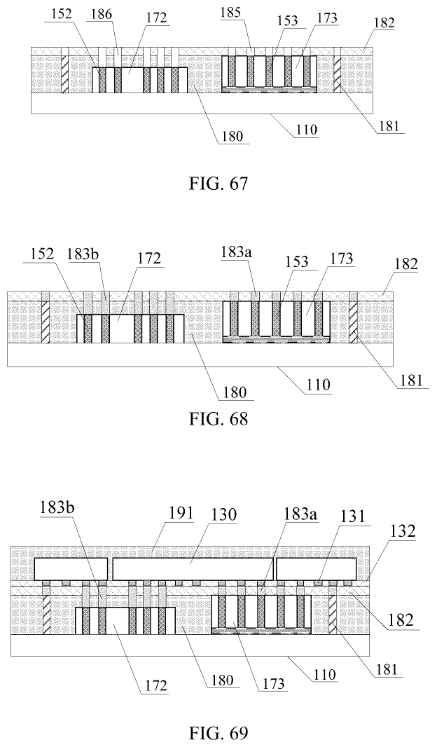

As shown in FIG. 67, the second passivation layer 182 may be formed on the back surfaces of the plurality of third silicon interposer sub-plates 173 after thinning and on the surface of the first plastic encapsulation layer 180 surrounding the plurality of second silicon interposer sub-plates 172 away from the plurality of second silicon interposer sub-plates 172.

As shown in FIG. 67, the second passivation layer 182 may be patterned using processes such as photolithography and etching, and a plurality of first openings 185 may be formed on the second passivation layer 182 corresponding to the plurality of third silicon interposer sub-plates 173. A plurality of second openings 186 may be formed on the second sub-passivation layer 182 corresponding to the plurality of second silicon interposer sub-plates 172. The depth of the plurality of second openings 186 may be larger than the depth of the plurality of first openings 185, and the bottom of the plurality of second openings 186 may extend to the second conductive connection structures 152 and correspond to the second conductive connection structures 152. The depth of the plurality of first openings 185 may also extend to the third conductive connection structures 153 and correspond to the third conductive connection structures 153.

As shown in FIG. 68, first sub-metal pads 183a and second sub-metal pads 183b may be respectively formed in the plurality of first openings 185 and the plurality of second openings 186 through processes such as electroplating or sputtering. The length dimension of the second sub-metal pads 183b may be larger than the length dimension of the first sub-metal pads 183a.

As shown in FIG. 69, the first passivation layer 132 and the second passivation layer 182 may be bonded and connected. The first metal pads 131 may be bonded and connected to the first sub-metal pads 183a and the second sub-metal pads 183b respectively.

That is, the first bonding structure may include the first passivation layer 132, the second passivation layer 182, the first metal pads 131, the second sub-metal pads 183b, corresponding to the plurality of second silicon interposer sub-plates 172.

The second bonding structure may include the first passivation layer 132, the second passivation layer 182, the first metal pads 131, the first sub-metal pads 183a, corresponding to the plurality of third silicon interposer sub-plates 173.

The side of the plurality of chips 130 may be bonded to the back surfaces of plurality of second silicon interposer sub-plates 172 and the plurality of third silicon interposer sub-plates 173 through the first bonding structure and the second bonding structure.

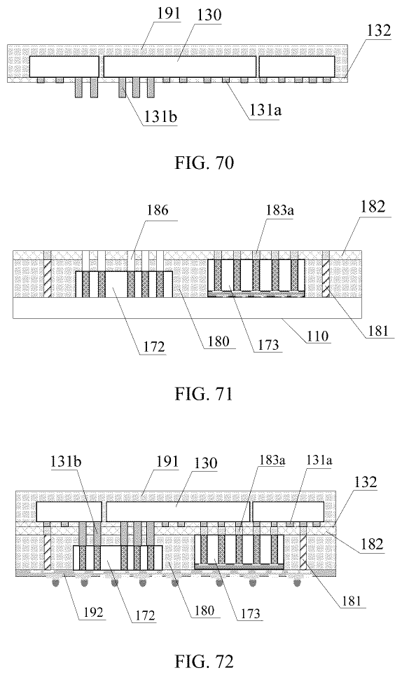

In another embodiment shown in FIG. 70 to FIG. 72, a plurality of second silicon interposer sub-plates 172 and a plurality of third silicon interposer sub-plates 173 may be selected as the plurality of target silicon interposer sub-plates. The plurality of third silicon interposer sub-plates 173 may have a height higher than the height of the plurality of second silicon interposer sub-plates 172.

As shown in FIG. 70, a second plastic encapsulation layer 191 may be formed on a side of the plurality of chips 130 away from the plurality of target silicon interposer sub-plates.

As shown in FIG. 71, the first plastic encapsulation layer 180 may be formed on the back surfaces of the plurality of second silicon interposer sub-plates 172 and the plurality of third silicon interposer sub-plates 173. A plurality of first through holes may be formed in the first plastic encapsulation layer 180 along the thickness direction of the first plastic encapsulation layer 180, and the plurality of first through holes may be filled with conductive materials to form the plurality of first interconnection conductive pillars 181.

As shown in FIG. 71, a side of the first plastic encapsulation layer 180 away from the plurality of target silicon interposer sub-plates may be thinned to expose the conductive connection structures on the back surfaces of target silicon interposer sub-plates with a higher height among the plurality of target silicon interposer sub-plates. That is, the side of the first plastic encapsulation layer 180 away from the plurality of target silicon interposer sub-plates may be thinned to expose the third conductive connection structures 153 on the back surfaces of the plurality of third silicon interposer sub-plates 173. The back surfaces of the plurality of second silicon interposer sub-plates 172 may still be wrapped by the first plastic encapsulation layer 180.

As shown in FIG. 70, the first passivation layer 132 may be formed on the side of the plurality of chips 130 and the second plastic encapsulation layer 191 facing the plurality of target silicon interposer sub-plates. The first passivation layer 132 may be patterned using processes such as photolithography and etching. The first sub-metal pads 131a may be formed at positions on the patterned first passivation layer 132 corresponding to the plurality of third silicon interposer sub-plates 173, and the second sub-metal pads 131b may be formed at positions on the patterned first passivation layer 132 corresponding to the plurality of second silicon interposer sub-plates 172. The length of the second sub-metal pads 131b corresponding to the plurality of second silicon interposer sub-plates 172 may be larger than the length of the first sub-metal pads 131a corresponding to the plurality of third silicon interposer sub-plates 173. In some other embodiments, the first passivation layer 132 may be formed after forming the first sub-metal pads 131a and the second sub-metal pads 131b.

As shown in FIG. 71, third sub-metal pads 183a may be formed on the back surfaces of the plurality of third silicon interposer sub-plates 173.

As shown in FIG. 71, the second passivation layer 182 may be formed on the third sub-metal pads 183a and on the surface of the first plastic encapsulation layer 180 corresponding to the back surfaces of the plurality of second silicon interposer sub-plates 172.

As shown in FIG. 71, the second passivation layer 182 may be patterned using processes such as photolithography and etching, and a plurality of second openings 186 may be formed on the second sub-passivation layer 182 corresponding to the plurality of second silicon interposer sub-plates 172. The depth of the plurality of second openings 186 may be consistent with the length of the second sub-metal pads 131b corresponding to the plurality of second silicon interposer sub-plates 172.

As shown in FIG. 72, the first passivation layer 132 and the second passivation layer 182 may be bonded and connected. The first sub-metal pads 131a corresponding to the plurality of third silicon interposer sub-plates 173 may be bonded and connected to the third sub-metal pads 183a, and the second sub-metal pads 131b corresponding to the plurality of second silicon interposer sub-plates 172 may be inserted into the corresponding plurality of second openings 186.

That is, the first bonding structure may include the first passivation layer 132, the second passivation layer 182, and the second sub-metal pads 131b, corresponding to the plurality of second silicon interposer sub-plates 172.

The second bonding structure may include the first passivation layer 132, the second passivation layer 182, the first sub-metal pads 131a, and the third sub-metal pads 183a, corresponding to the plurality of third silicon interposer sub-plates 173.

The side of the plurality of chips 130 may be bonded to the back surfaces of plurality of second silicon interposer sub-plates 172 and the plurality of third silicon interposer sub-plates 173 through the first bonding structure and the second bonding structure.

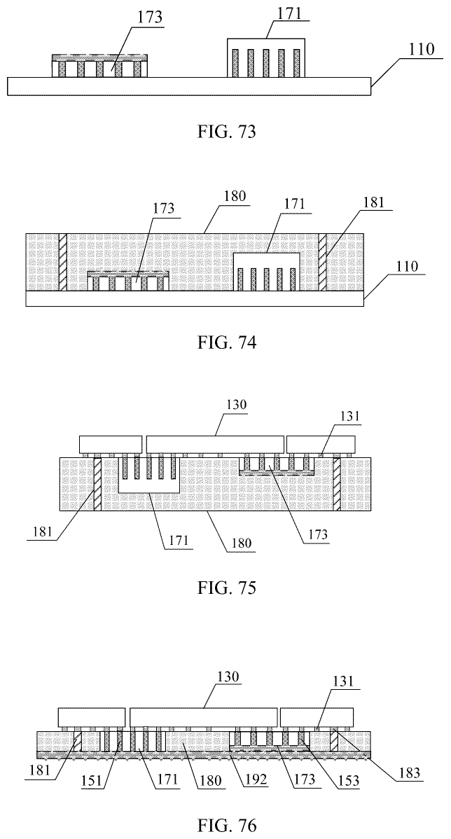

In another embodiment shown in FIG. 73 to FIG. 76, a plurality of first silicon interposer sub-plates 171 and a plurality of third silicon interposer sub-plates 173 may be selected as the plurality of target silicon interposer sub-plates. The plurality of third silicon interposer sub-plates 173 may have a height lower than the height of the plurality of first silicon interposer sub-plates 171.

As shown in FIG. 73, the front surfaces of the plurality of first silicon interposer sub-plates 171 and the back surfaces of the plurality of third silicon interposer sub-plates 173 may be fixed to a carrier 110. In one embodiment, an adhesive layer may be used to fix the front surfaces of the plurality of first silicon interposer sub-plates 171 and the back surfaces of the plurality of third silicon interposer sub-plates 173 to the carrier 110.

As shown in FIG. 74, the first plastic encapsulation layer 180 may be formed on the back surfaces of the plurality of first silicon interposer sub-plates 171 and the front surfaces of the plurality of third silicon interposer sub-plates 173. A plurality of first through holes may be formed in the first plastic encapsulation layer 180 along the thickness direction of the first plastic encapsulation layer 180, and the plurality of first through holes may be filled with conductive materials to form the plurality of first interconnection conductive pillars 181.

As shown in FIG. 75, the first metal pads 131 may be sequentially formed on the side of the plurality of chips 130 and the second plastic encapsulation layer 191 facing the back surfaces of the plurality of first silicon interposer sub-plates 171 and the front surfaces of the plurality of third silicon interposer sub-plates 173. The first metal pad 131 may be made of a material including metal copper or other metal materials, which is not limited in this embodiment.

As shown in FIG. 75, the carrier 110 may be removed, and the plurality of chips 130 may be mounted on the front surfaces of the plurality of first silicon interposer sub-plates 171 and the back surfaces of the plurality of third silicon interposer sub-plates 173 through the first metal pads 131 using the flip-chip process.

As shown in FIG. 76, a side of the first plastic encapsulation layer 180 away from the carrier 110 may be thinned to expose the conductive connection structures on the back surfaces of the plurality of first silicon interposer sub-plates 171 and the plurality of silicon through holes on the back surfaces of the plurality of first silicon interposer sub-plates 171, and the redistribution layer and the first interconnection conductive pillars 181 on the front surfaces of the plurality of third silicon interposer sub-plates 173, may be exposed.

After thinning, the back surfaces of the plurality of first silicon interposer sub-plates 171 and the front surfaces of the plurality of third silicon interposer sub-plates 173 may be flush. That is, the back surfaces of the plurality of first silicon interposer sub-plates 171 may need to be thinned to be flush with the front surfaces of the plurality of third silicon interposer sub-plates 173 to prepare for subsequent packaging.

As shown in FIG. 76, the first circuit layer 192 may be formed on the back surfaces of the plurality of first silicon interposer sub-plates 171 and the front surfaces of the plurality of third silicon interposer sub-plates 173. The package structure may be electrically connected to the outside world through the first circuit layer 192. The first circuit layer 192 may include a redistribution layer and solder balls, or may include other circuit layers. This embodiment is not limited.

In the present disclosure, the large silicon interposer plate may be cut into small silicon interposer blocks to avoid warping and cracking of the silicon interposers during the thinning process. The plurality of silicon interposer blocks with different specifications may be combined according to the installation requirements of different chips, and may be installed with the correspondingly chips. Also, the chips and the silicon interposer blocks may be molded at one time. The overall area of the silicon interposers and the spacing between individual chips may be reduced, greatly improving packaging efficiency and overall integration level.

The present disclosure also provides a chip packaging structure. The chip packaging structure may include: a plurality of silicon interposers, a first plastic encapsulation layer, and a plurality of chips. Each of the plurality of silicon interposers may be provided with conductive connection structures, and conductive connection structures of at least one of the plurality of silicon interposers may be different from conductive connection structures of others of the plurality of silicon interposers. The first plastic encapsulation layer may wrap the plurality of silicon interposers. The plurality of chips may be interconnected to the plurality of silicon interposers through a bonding structure.

For the detailed implementation of the chip packaging structure embodiments, the reference may be made to the previous method embodiments.

In the present disclosure, the conductive connection structures may be formed on the plurality of silicon wafers respectively to form the plurality of silicon interposer plates. The conductive connection structures on at least one silicon interposer plate may have different specifications from the conductive connection structures on other silicon interposer plates. Each silicon interposer plate may be cut to form the plurality of silicon interposer sub-plates, and then the plurality of silicon interposer sub-plates may be reorganized according to the preset packaging requirements and the plurality of target silicon interposer sub-plates may be selected from the plurality of silicon interposer sub-plates. The plurality of chips may be interconnected to the plurality of target silicon interposer sub-plates, avoiding warpage or cracking of the plurality of target silicon interposer sub-plates during chip packaging. Each silicon interposer plate may be cut to form the plurality of silicon interposer sub-plates, and the plurality of silicon interposer sub-plates may be reorganized as the plurality of target silicon interposer sub-plates which may be molded with the plurality of chips at one time, improving the integration of chip packaging.

The embodiments disclosed herein are exemplary only. Other applications, advantages, alternations, modifications, or equivalents to the disclosed embodiments are obvious to those skilled in the art and are intended to be encompassed within the scope of the present disclosure.

What is claimed is:

1. A fan-out chip packaging method, comprising:
providing a carrier, a plurality of silicon wafers, and a plurality of chips;
forming conductive connection structures on the plurality of silicon wafers respectively to form a plurality of silicon interposer plates; wherein the conductive connection structures on at least one of the plurality of silicon interposer plates are different from the conductive connection structures on others of the plurality of silicon interposer plates;
cutting each of the plurality of silicon interposer plates respectively to obtain a plurality of silicon interposer sub-plates;
selecting a plurality of target silicon interposer sub-plates from the plurality of silicon interposer sub-plates according to preset packaging requirements, and fixing the plurality of target silicon interposer sub-plates on the carrier, wherein the conductive connection structures on at least one of the plurality of target silicon interposer sub-plates are different from the conductive connection structures on others of the plurality of target silicon interposer sub-plates;
forming a first plastic encapsulation layer on a side of the plurality of target silicon interposer sub-plates away from the carrier; and
interconnecting the plurality of chips to the plurality of target silicon interposer sub-plates.

2. The method according to claim 1, wherein:
forming the conductive connection structures on the plurality of silicon wafers respectively to form the plurality of silicon interposer plates, includes:
forming a plurality of blind holes on a front surface of at least one of the plurality of silicon wafers, wherein the plurality blind holes on at least one of the plurality of silicon interposer plates are different from the plurality blind holes on other silicon interposer plates of the plurality of silicon interposer plates; and filling the plurality of blind holes with conductive materials to form the conductive connection structures, or,
forming a plurality of blind holes on a front surface of at least one of the plurality of silicon wafers; filling the plurality of blind holes with conductive materials; and thinning back surfaces of the plurality of silicon wafers until exposing the plurality of blind holes to form the conductive connection structures, or,
forming a plurality of blind holes on a front surface of at least one of the plurality of silicon wafers; filling the plurality of blind holes with conductive materials; forming a redistribution layer on the plurality of blind holes; and thinning back surfaces of the plurality of silicon wafers until exposing the plurality of blind holes to form the conductive connection structures, or,
forming a plurality of blind holes on a front surface of at least one of the plurality of silicon wafers; filling the plurality of blind holes with conductive materials; forming a redistribution layer on the plurality of blind holes; forming a plurality of soldering balls on the redistribution layer; and thinning back surfaces of the plurality of silicon wafers until exposing the plurality of blind holes to form the conductive connection structures.

3. The method according to claim 1, wherein:
interconnecting the plurality of chips to the plurality of target silicon interposer sub-plates includes: forming a second plastic encapsulation layer on a side of the plurality of chips away from the plurality of target silicon interposer sub-plates; and interconnecting a side of the plurality of chips and the second plastic encapsulation layer facing the plurality of target silicon interposer sub-plates to a side of the plurality of target silicon interposer sub-plates facing the plurality of chips through a bonding structure;
after interconnecting the plurality of chips to the plurality of target silicon interposer sub-plates, the method further includes: forming a first circuit layer on another side of the plurality of target silicon interposer sub-plates away from the plurality of chips;
after forming the first plastic encapsulation layer on the side of the plurality of target silicon interposer sub-plates away from the carrier or after interconnecting the plurality of chips to the plurality of target silicon interposer sub-plates, the method further includes: forming a plurality of first through holes in the first plastic encapsulation layer along a thickness direction of the first plastic encapsulation layer; and filling the plurality of first through holes with conductive materials to form a plurality of first interconnection conductive pillars, wherein two ends of each of the plurality of first interconnection conductive pillars are electrically connected to the plurality of chips and the first circuit layer respectively; and
after forming the first circuit layer on the side of the plurality of target silicon interposer sub-plates away from the plurality of chips, the method further includes: forming a plurality of second through holes penetrating through the first plastic encapsulation layer and the second plastic encapsulation layer along the thickness direction of the first plastic encapsulation layer and the second plastic encapsulation layer; filling the plurality of second through holes with conductive materials to form a plurality of second interconnection conductive pillars; and forming a second circuit layer on a side of the second plastic encapsulation layer away from the plurality of target silicon interposer sub-plates, wherein two ends of each of the plurality of second interconnection conductive pillars are electrically connected to the first circuit layer and the second circuit layer respectively.

4. The method according to claim 1, wherein:
fixing the plurality of target silicon interposer sub-plates on the carrier includes fixing front surfaces of the plurality of target silicon interposer sub-plates on the carrier, wherein the plurality of target silicon interposer sub-plates has a same height;
forming the first plastic encapsulation layer on the sides of the plurality of target silicon interposer sub-plates away from the carrier includes forming the first plastic encapsulation layer on back surfaces of the plurality of target silicon interposer sub-plates; and
interconnecting the plurality of chips to the plurality of target silicon interposer sub-plates includes bonding the plurality of chips to the plurality of target silicon interposer sub-plates.

5. The method according to claim 4, wherein:
bonding the plurality of chips to the plurality of target silicon interposer sub-plates includes: removing the carrier; and bonding a side of the plurality of chips facing the plurality of target silicon interposer sub-plates to the front surfaces of the plurality of target silicon interposer sub-plates through a bonding structure; and
after bonding the plurality of chips to the plurality of target silicon interposer sub-plates, the method further includes: thinning a side of the first plastic encapsulation layer away from the plurality of target silicon interposer sub-plates to expose the conductive connection structures on the back surfaces of the plurality of target silicon interposer sub-plates; and forming a first circuit layer on the back surfaces of the plurality of target silicon interposer sub-plates.

6. The method according to claim 4, wherein:
bonding the plurality of chips to the plurality of target silicon interposer sub-plates includes:
forming a second plastic encapsulation layer on the side of the plurality of chips away from the plurality of target silicon interposer sub-plates;
thinning the side of the first plastic encapsulation layer away from the carrier to expose the conductive connection structures on the back surfaces of the plurality of target silicon interposer sub-plates; and
bonding the plurality of chips and the side of the second plastic encapsulation layer facing the plurality of target silicon interposer sub-plates to the back surfaces of the plurality of target silicon interposer sub-plates through the bonding structure; and
after bonding the plurality of chips to the plurality of target silicon interposer sub-plates, the method further includes: removing the carrier and forming a first circuit layer on the front surfaces of the plurality of target silicon interposer sub-plates.

7. The method according to claim 1, wherein:
fixing the plurality of target silicon interposer sub-plates on the carrier includes fixing back surfaces of the plurality of target silicon interposer sub-plates on the carrier, wherein the plurality of target silicon interposer sub-plates has a same height; and
forming the first plastic encapsulation layer on the sides of the plurality of target silicon interposer sub-plates away from the carrier includes forming the first plastic encapsulation layer on front surfaces of the plurality of target silicon interposer sub-plates.

8. The method according to claim 7, wherein:
the conductive structures of at least one of the plurality of target silicon interposer sub-plates includes a plurality of blind holes filled with conductive materials;
interconnecting the plurality of chips to the plurality of target silicon interposer sub-plates includes: thinning the side of the first plastic encapsulation layer away from the carrier to expose the conductive connection structures on the front surfaces of the plurality of target silicon interposer sub-plates; and interconnecting a side of the plurality of chips facing the plurality of target silicon interposer sub-plates to the front surfaces of the plurality of target silicon interposer sub-plates through a bonding structure; and
after interconnecting the plurality of chips to the plurality of target silicon interposer sub-plates, the method further includes:
removing the carrier and thinning the back surfaces of the plurality of target silicon interposer sub-plates to expose the conductive connection structures on the back surfaces of the plurality of target silicon interposer sub-plates; and
forming a first circuit layer on the back surfaces of the plurality of thinned target silicon interposer sub-plates.

9. The method according to claim 7, wherein:
the conductive structures of at least one of the plurality of target silicon interposer sub-plates includes a plurality of blind holes filled with conductive materials;
interconnecting the plurality of chips to the plurality of target silicon interposer sub-plates further includes:
removing the carrier and thinning the back surfaces of the plurality of target silicon interposer sub-plates to expose the conductive connection structures on the back surfaces of the plurality of target silicon interposer sub-plates; and
interconnecting a side of the plurality of chips facing the plurality of target silicon interposer sub-plates to the back surfaces of the plurality of thinned target silicon interposer sub-plates through a bonding structure; and
after interconnecting the plurality of chips to the plurality of target silicon interposer sub-plates, the method further includes: thinning the side of the first plastic encapsulation layer away from the carrier to expose the front surfaces of the plurality of target silicon interposer sub-plates; and forming a first circuit layer on the front surfaces of the plurality of thinned target silicon interposer sub-plates.

10. The method according to claim 1, wherein:
fixing the plurality of target silicon interposer sub-plates on the carrier includes: fixing a first surface of at least one of the plurality of target silicon interposer sub-plates on the carrier, and fixing second surfaces of others of the plurality of target silicon interposer sub-plates on the carrier, wherein the plurality of target silicon interposer sub-plates has a same height.

11. The method according to claim 1, wherein:
fixing the plurality of target silicon interposer sub-plates on the carrier includes fixing front surfaces of the plurality of target silicon interposer sub-plates on the carrier, wherein a height of at least one of the plurality of target silicon interposer sub-plates is different from heights of others of the plurality of target silicon interposer sub-plates.

12. The method according to claim 11, wherein:
interconnecting the plurality of chips to the plurality of target silicon interposer sub-plates includes:
forming a second plastic encapsulation layer on the side of the plurality of chips away from the plurality of target silicon interposer sub-plates; and
removing the carrier and bonding the sides of the plurality of chips and the second plastic encapsulation layer facing the plurality of target silicon interposer sub-plates to the front surfaces of the plurality of target silicon interposer sub-plates through the bonding structure; and
after interconnecting the plurality of chips to the plurality of target silicon interposer sub-plates, the method further includes:
thinning the side of the first plastic encapsulation layer away from the plurality of chips to expose the conductive connection structures on the back surfaces of the plurality of target silicon interposer sub-plates, wherein back surfaces of target silicon interposer sub-plates with lower heights of the plurality of target silicon interposer sub-plates are flush with back surfaces of other target silicon interposer sub-plates of the plurality of target silicon interposer sub-plates after thinning; and
forming a first circuit layer on the back surfaces of the plurality of target silicon interposer sub-plates.

13. The method according to claim 11, wherein:
interconnecting the plurality of chips to the plurality of target silicon interposer sub-plates includes:
forming a second plastic encapsulation layer on the side of the plurality of chips away from the plurality of target silicon interposer sub-plates;
thinning the side of the first plastic encapsulation layer away from the plurality of target silicon interposer sub-plates to expose the conductive connection structures on the back surfaces of the plurality of target silicon interposer sub-plates, wherein back surfaces of target silicon interposer sub-plates with lower heights of the plurality of target silicon interposer sub-plates are flush with back surfaces of other target silicon interposer sub-plates of the plurality of target silicon interposer sub-plates after thinning; and
interconnecting the sides of the plurality of chips and the second plastic encapsulation layer facing the plurality of target silicon interposer sub-plates to the back surfaces of the plurality of target silicon interposer sub-plates through the bonding structure; and
after interconnecting the plurality of chips to the plurality of target silicon interposer sub-plates, the method further includes: removing the carrier and forming a first circuit layer on the front surfaces of the plurality of target silicon interposer sub-plates.

14. The method according to claim 11, wherein:
interconnecting the plurality of chips to the plurality of target silicon interposer sub-plates includes:
forming a second plastic encapsulation layer on the side of the plurality of chips away from the plurality of target silicon interposer sub-plates;
thinning the side of the first plastic encapsulation layer away from the plurality of target silicon interposer sub-plates to expose the conductive connection structures on the back surfaces of target silicon interposer sub-plates with higher heights of the plurality of target silicon interposer sub-plates;
bonding the sides of the plurality of chips and the second plastic encapsulation layer facing the plurality of target silicon interposer sub-plates to the back surfaces of target silicon interposer sub-plates with the lower heights among the plurality of target silicon interposer sub-plates through a first bonding structure; and
bonding the sides of the plurality of chips and the second plastic encapsulation layer facing the plurality of target silicon interposer sub-plates to the back surfaces of target silicon interposer sub-plates with the higher heights among the plurality of target silicon interposer sub-plates through a second bonding structure, wherein the first bonding structure has a height higher than a height of the second bonding structure; and
after interconnecting the plurality of chips to the plurality of target silicon interposer sub-plates, the method further includes: removing the carrier and forming a first circuit layer on the front surfaces of the plurality of target silicon interposer sub-plates.

15. The method according to claim 1, wherein:
fixing the plurality of target silicon interposer sub-plates on the carrier includes fixing back surfaces of the plurality of target silicon interposer sub-plates on the carrier, wherein a height of at least one of the plurality of target silicon interposer sub-plates is different from heights of others of the plurality of target silicon interposer sub-plates.

16. The method according to claim 15, wherein:
interconnecting the plurality of chips to the plurality of target silicon interposer sub-plates includes: removing the carrier and bonding the sides of the plurality of chips facing the plurality of target silicon interposer sub-plates to the back surfaces of the plurality of target silicon interposer sub-plates through a bonding structure; and
after interconnecting the plurality of chips to the plurality of target silicon interposer sub-plates, the method further includes:
thinning the side of the first plastic encapsulation layer away from the plurality of chips to expose the conductive connection structures on the front surfaces of the plurality of target silicon interposer sub-plates, wherein the front surfaces of the plurality of target silicon interposer sub-plates are flush after thinning; and
forming a first circuit layer on the front surfaces of the plurality of target silicon interposer sub-plates.

17. The method according to claim 15, wherein:
interconnecting the plurality of chips to the plurality of target silicon interposer sub-plates includes:
forming a second plastic encapsulation layer on the side of the plurality of chips away from the plurality of target silicon interposer sub-plates;
thinning the side of the first plastic encapsulation layer away from the carrier to expose the conductive connection structures on the front surfaces of the plurality of target silicon interposer sub-plates, wherein b the front surfaces of the plurality of target silicon interposer sub-plates are flush after thinning; and
bonding the sides of the plurality of chips and the second plastic encapsulation layer facing the plurality of target silicon interposer sub-plates to the front surfaces of the plurality of target silicon interposer sub-plates through the bonding structure; and
after interconnecting the plurality of chips to the plurality of target silicon interposer sub-plates, the method further includes: removing the carrier and forming a first circuit layer on the back surfaces of the plurality of target silicon interposer sub-plates.

18. The method according to claim 15, wherein:
interconnecting the plurality of chips to the plurality of target silicon interposer sub-plates includes:
forming a second plastic encapsulation layer on the side of the plurality of chips away from the plurality of target silicon interposer sub-plates;
thinning the side of the first plastic encapsulation layer away from the plurality of target silicon interposer sub-plates to expose the conductive connection structures on the front surfaces of target silicon interposer sub-plates with higher heights of the plurality of target silicon interposer sub-plates;
bonding the sides of the plurality of chips and the second plastic encapsulation layer facing the plurality of target silicon interposer sub-plates to the front surfaces of target silicon interposer sub-plates with the lower heights among the plurality of target silicon interposer sub-plates through a first bonding structure; and
bonding the sides of the plurality of chips and the second plastic encapsulation layer facing the plurality of target silicon interposer sub-plates to the front surfaces of target silicon interposer sub-plates with the higher heights among the plurality of target silicon interposer sub-plates through a second bonding structure, wherein the first bonding structure has a height higher than a height of the second bonding structure; and
after interconnecting the plurality of chips to the plurality of target silicon interposer sub-plates, the method further includes: removing the carrier and forming a first circuit layer on the back surfaces of the plurality of target silicon interposer sub-plates.

19. The method according to claim 1, wherein:
fixing the plurality of target silicon interposer sub-plates on the carrier includes: fixing a first surface of at least one of the plurality of target silicon interposer sub-plates on the carrier, and fixing second surfaces of others of the plurality of target silicon interposer sub-plates on the carrier, wherein a height of at least one of the plurality of target silicon interposer sub-plates is different from heights of others of the plurality of target silicon interposer sub-plates;
a first surface of at least one target silicon interposer sub-plate whose conductive connection structures include a plurality of blind holes or a plurality of silicon through holes filled with conductive materials is fixed to the carrier, wherein the height of the at least one target silicon interposer sub-plate is higher than others of the plurality of target silicon interposer sub-plates;
interconnecting the plurality of chips to the plurality of target silicon interposer sub-plates includes:
removing the carrier and bonding the sides of the plurality of chips facing the plurality of target silicon interposer sub-plates to a side of the plurality of target silicon interposer sub-plates facing the carrier through a bonding structure, or
forming a second plastic encapsulation layer on the side of the plurality of chips away from the plurality of target silicon interposer sub-plates; thinning the side of the first plastic encapsulation layer away from the carrier to expose the conductive connection structures on the side of the plurality of target silicon interposer sub-plates away from the carrier, wherein the side of the plurality of target silicon interposer sub-plates away from the carrier are flush after thinning; and bonding the sides of the plurality of chips and the second plastic encapsulation layer facing the plurality of target silicon interposer sub-plates to the side of the plurality of target silicon interposer sub-plates away from the carrier through the bonding structure, or
forming a second plastic encapsulation layer on the side of the plurality of chips away from the plurality of target silicon interposer sub-plates, thinning the side of the first plastic encapsulation layer away from the carrier to expose the conductive connection structures on the side of target silicon interposer sub-plates with higher heights of the plurality of target silicon interposer sub-plates away from the carrier, bonding the sides of the plurality of chips and the second plastic encapsulation layer facing the plurality of target silicon interposer sub-plates to the side of target silicon interposer sub-plates with the lower heights among the plurality of target silicon interposer sub-plates away from the carrier through a first bonding structure, and bonding the sides of the plurality of chips and the second plastic encapsulation layer facing the plurality of target silicon interposer sub-plates to the side of target silicon interposer sub-plates with the higher heights among the plurality of target silicon interposer sub-plates away from the carrier through a second bonding structure, wherein the first bonding structure has a height higher than a height of the second bonding structure; and
after interconnecting the plurality of chips to the plurality of target silicon interposer sub-plates, the method further includes: thinning the side of the first plastic encapsulation layer away from the plurality of chips to expose the conductive connection structures on the side of the plurality of target silicon interposer sub-plates away from the carrier; and forming a first circuit layer on the side of the plurality of target silicon interposer sub-plates away from the carrier.

20. A fan-out chip packaging structure, comprising:
a plurality of silicon interposers, wherein each of the plurality of silicon interposers is provided with conductive connection structures and conductive connection structures of at least one of the plurality of silicon interposers are different from conductive connection structures of others of the plurality of silicon interposers;
a first plastic encapsulation layer wrapping the plurality of silicon interposers; and
a plurality of chips, wherein the plurality of chips is interconnected to the plurality of silicon interposers through a bonding structure.
